(19) United States
(12) Patent Application Publication
(10) Pub. No.: US 2007/0172708 A1
(43) Pub. Date: Jul. 26, 2007

(54) Fuel cell system failure diagnosis method, failure diagnosis device using same, and fuel cell system

(76) Inventors: Yasuo Takebe, Kyoto (JP); Makoto Uchida, Osaka (JP)

Correspondence Address: MCDERMOTT WILL & EMERY LLP, 600 13TH STREET, NW, WASHINGTON, DC, 20005-3096, US

(21) Appl. No.: 10/592,500

(22) PCT Filed: Mar. 11, 2005
(86) PCT No.: PCT/JP05/04365

§ 371 Date: Sep. 12, 2006

(30) Foreign Application Priority Data
Mar. 12, 2004 (JP) 2004-071282

(51) Int. Cl. H01M 8/04; H01M 8/06; G01R 31/02

(52) U.S. Cl. 429/13; 429/22; 429/19; 324/537; 429/34

(57) ABSTRACT

It was difficult to specify a portion which is a cause of a power generation abnormality of a fuel cell which performs the power generation by feeding an oxygen-containing oxidizer gas into a cathode and feeding a hydrogen-containing fuel gas into an anode. A failure diagnosis method of a fuel cell system, which includes a step for computing an impedance in a prescribed portion of a fuel cell of a fuel cell system from a signal obtained by superposing an alternating current on a direct current as generated from the fuel cell system under a certain operation condition, wherein when in comparison of the impedance with an impedance as computed under a previously determined standard operation condition, an abnormality is present in the prescribed portion of the fuel cell, whether a cause of the abnormality of the prescribed portion resides in any one or plural prescribed sites constituting the fuel cell system is determined by using the comparison result.

### RELATED APPLICATION

This application is a national phase of PCT/JP2005/004365 filed on Mar. 11, 2005, which claims priority from Japanese Application No. 2004-071282 filed on Mar. 12, 2004, the disclosures of which Applications are incorporated by reference herein. The benefit of the filing and priority dates of the International and Japanese Applications is respectfully requested.

### FIELD OF THE INVENTION

The present invention relates to a diagnosis method of a fuel cell system for specifying the site of a failure at the time of the occurrence of a power generation abnormality or a lowering of power generation voltage of, for example, a fuel cell of a polymer electrolyte type or the like and to a failure diagnosis device using the same or the like.

### BACKGROUND ART

A fuel cell performs the power generation by feeding an oxygen-containing oxidizer gas into a cathode and feeding a hydrogen-containing fuel gas into an anode and is constructed of a single cell made up of one pair of a cathode and an anode or a fuel cell stack in which plural single cells are connected in series.

As to the fuel gas which is fed into a fuel cell, a hydrogen-containing gas is produced from a fuel such as a city gas via a hydrogen generation device. As to the oxidizer gas, in general, air is fed by a blower. Furthermore, the fuel gas and the oxidizer gas are properly humidified via a humidifier or the like and fed.

A peripheral device for actuating such a fuel cell is constructed of a number of members, which are operated together complicatedly.

In the case where a part of the peripheral device fails, a power generation abnormality of the fuel cell occurs as a consequence. In order to repair the site of a failure, it is inevitable to specify the site of a failure. In addition, since it is non-economical to move the whole of the fuel cell system for the purpose of repairing the failure, it is desired to specify the site of a failure on the spot where the fuel cell system is placed.

In general, though the power generation abnormality of a fuel cell is detected by monitoring the voltage of the single cell, it is difficult to judge even a cause of the power generation abnormality by this method.

More concretely, it is impossible to judge whether the cause of a lowering of the voltage of the single cell resides in an increase of diffusion resistance due to hindrance of the gas diffusion or in an increase of the reaction resistance due to a lowering of the reactivity of electrodes.

As technologies for judging the cause of such a power generation abnormality, there is a technology for measuring an alternating current impedance regarding a specific frequency in advance, impressing an alternating current with that specific frequency during the power generation to measure an impedance and comparing the both (see, for example, JP-A-2002-367650).

More concretely, the alternating current voltage is impressed at a frequency of at least 5 Hz and 40 Hz, and diffusion resistance and reaction resistance are determined from an imaginary number part of impedance at the respective frequencies.

### SUMMARY OF THE INVENTION

However, according to the foregoing conventional judging technologies, though the presence or absence of an abnormality of a fuel cell can be detected, it is difficult to specify a place where the site of a failure as a cause of the abnormality exists in the entire fuel cell system.

That is, though it is possible to specify whether a lowering of the voltage is caused due to hindrance of the gas diffusion or due to a lowering of the reactivity of electrodes, it is impossible to further specify even the site of a failure which is a primary factor for hindering the gas diffusion or a cause for reducing the reactivity of electrodes.

Taking into consideration the foregoing conventional problems, an object of the present invention is to provide a diagnosis method of a fuel cell system in which in maintenance of a fuel cell system, when a power generation abnormality or a lowering of power generation voltage of a fuel cell occurs, the site of a failure can be specified, thereby smoothly achieving repair and a failure diagnosis device or the like.

To achieve the above object, the 1st aspect of the present invention is a failure diagnosis method of a fuel cell system, which includes a step for computing an impedance in a prescribed portion of a fuel cell of a fuel cell system from a signal obtained by superposing an alternating current on a direct current generated from the fuel cell system under a certain operation condition, wherein

when in comparison of the impedance with an impedance as computed under a previously determined standard operation condition, an abnormality is present in the prescribed portion of the fuel cell, whether a cause of the abnormality of the prescribed portion resides in any one or plural prescribed sites constituting the fuel cell system is determined by using the comparison result.

According to such a present invention, it is possible to judge that a cause of the change in impedance of a prescribed portion of the fuel cell resides in any one of prescribed places of the fuel cell system, and in the case where an abnormality is generated in the fuel cell system, it is possible to rapidly specify a cause of the abnormality.

The 2nd aspect of the present invention is the failure diagnosis method of a fuel cell system according to the 1st aspect of the present invention, wherein the determination is to separate whether the cause of the abnormality of the prescribed portion resides in the fuel cell per se which the fuel cell system has or the prescribed sites other than the fuel cell.

The 3rd aspect of the present invention is the failure diagnosis method of a fuel cell system according to the 1st or the 2nd aspect of the present invention, comprising the steps of:

performing the determination by using a corresponding relation between an operation condition of each prescribed site of the fuel cell system and an impedance of each prescribed portion of the fuel cell under the standard operation condition as a characteristic profile,

as the certain operation condition, changing the operation condition of the prescribed site more greatly than the standard operation condition and comparing a diagnosis impedance as measured corresponding to the change with an impedance of the characteristic profile, and

making the judgment such that when a change of the diagnosis impedance from the impedance of the characteristic profile can be judged on the basis of the characteristic profile, the cause of the change resides in the prescribed site, whereas when the change cannot be judged, the cause of the change does not reside in the prescribed site.

According to these present inventions, with respect to a cause of the change in impedance of a prescribed portion of the fuel cell, it is possible to rapidly specify the cause by distinguishing plural causes in individually specifying a prescribed place of the fuel cell system.

The 4th aspect of the present invention is the failure diagnosis method of a fuel cell system according to the 3rd aspect of the present invention, wherein

the fuel cell system includes a power generation section having the fuel cell; an oxidizer gas feed section for feeding an oxidizer gas for undergoing power generation of the fuel cell into the power generation section; and a hydrogen gas feed section having a reformer for feeding a hydrogen gas for undergoing power generation of the fuel cell into the power generation section,

the prescribed site includes at least one of a specific site within the hydrogen gas feed section, a specific site within the oxidizer gas feed section and a specific site within the power generation section, and

the determination is achieved by changing operation conditions of these specific sites.

The 5th aspect of the present invention is the failure diagnosis method of a fuel cell system according to the 4th aspect of the present invention, wherein

the specific site of the hydrogen gas feed section is a first pump for feeding water for reformation into the reformer, a booster for feeding a raw material into the reformer, and a burner for heating the reformer, and

the reformer is included as the prescribed site.

The 6th aspect of the present invention is the failure diagnosis method of a fuel cell system according to the 4th aspect of the present invention, wherein

the specific site of the oxidizer gas feed section is a blower for taking and introducing the outside air into the side of the fuel cell, a humidifier for humidifying the outside air as taken by the blower, and a second pump for feeding water into the humidifier, and

a filter as provided before the blower is included as the prescribed site.

The 7th aspect of the present invention is the failure diagnosis method of a fuel cell system according to the 4th aspect of the present invention, wherein

the specific site of the power generation section is the fuel cell and a third pump for feeding cooling water into the fuel cell, and

the fuel cell is included as the prescribed site.

The 8th aspect of the present invention is the failure diagnosis method of a fuel cell system according to the 1st aspect of the present invention, wherein

the specific site of the fuel cell is determined by considering the fuel cell as an equivalent circuit having the prescribed portion as a resistance and computing the impedance for every alternating current with a different frequency.

The 9th aspect of the present invention is the failure diagnosis method of a fuel cell system according to the 1st aspect of the present invention, wherein an amplitude of the alternating current has a size of substantially from 5% to 10% of the direct current value.

The 10th aspect of the present invention is a failure diagnosis device of a fuel cell system including

an alternating current source for feeding a frequency variable alternating current which is superposed on a direct current generated from a fuel cell of a fuel cell system,

an impedance computation instrument for computing an impedance corresponding to a prescribed portion of the fuel cell of the fuel cell system from a signal obtained by superposing the alternating current on the direct current, and

a diagnosis instrument in which when in comparison of the impedance with an impedance as computed under a previously determined standard operation condition, an abnormality is present in the prescribed portion of the fuel cell, whether a cause of the abnormality of the prescribed portion resides in any one or plural prescribed sites constituting the fuel cell system is determined by using the comparison result.

According to such a present invention, it is possible to judge that a cause of the change in impedance of a prescribed portion of the fuel cell resides in any one of prescribed places of the fuel cell system, and in the case where an abnormality is generated in the fuel cell system, it is possible to rapidly specify a cause of the abnormality.

The 11th aspect of the present invention is the failure diagnosis device of a fuel cell system according to the 10th aspect of the present invention, wherein the diagnosis instrument achieves the determination by

using a corresponding relation between an operation condition of each prescribed site of the fuel cell system and an impedance of each prescribed portion of the fuel cell under the standard operation condition as a characteristic profile,

as the certain operation condition, changing the operation condition of the prescribed site more greatly than the standard operation condition and comparing a diagnosis impedance as measured corresponding to the change with an impedance of the characteristic profile, and

making the judgment such that when a change of the diagnosis impedance from the impedance of the characteristic profile can be judged on the basis of the characteristic profile, its cause resides in that prescribed site, whereas when the change cannot be judged, its cause does not reside in that prescribed site.

According to such a present invention, with respect to a cause of the change in impedance of a prescribed portion of the fuel cell, it is possible to rapidly specify the cause by distinguishing plural causes in individually specifying a prescribed place of the fuel cell system.

The 12th aspect of the present invention is a fuel cell system having the failure diagnosis device of a fuel cell system according to the 10th or the 11th aspect of the present invention, which includes a power generation section having the fuel cell; an oxidizer gas feed section for feeding an oxidizer gas for undergoing power generation of the fuel cell into the power generation section; and a hydrogen gas feed section having a reformer for feeding a hydrogen gas for undergoing power generation of the fuel cell into the power generation section, wherein

the prescribed site includes at least one of a specific site within the hydrogen gas feed section, a specific site within the oxidizer gas feed section and a specific site within the power generation section, and

the determination instrument achieves the determination by changing operation conditions of these specific sites.

The 13th aspect of the present invention is the fuel cell system according to the 12th aspect of the present invention, which further includes a control instrument for changing operation conditions of the specific site within the hydrogen feed section, the specific site within the oxidizer gas feed section and the specific site within the power generation section, wherein

the diagnosis instrument achieves the determination by obtaining parameters of the changes of the operation condition from the control instrument.

The 14th aspect of the present invention is the fuel cell system according to the 12th aspect of the present invention, wherein

the specific site of the hydrogen gas feed section is a first pump for feeding water for reformation into a reformer, a booster for feeding a raw material into the reformer, and a burner for heating the reformer, and

the reformer is included as the prescribed site.

The 15th aspect of the present invention is the fuel cell system according to the 12th aspect of the present invention, wherein

the specific site of the oxidizer gas feed section is a blower for taking and introducing the outside air into the side of the fuel cell, a humidifier for humidifying the outside air as taken by the blower, and a second pump for feeding water into the humidifier, and

a filter as provided before the blower is included as the prescribed site.

The 16th aspect of the present invention is the fuel cell system according to the 12th aspect of the present invention, wherein

the specific site of the power generation section is the fuel cell and a third pump for feeding cooling water into the fuel cell, and

the fuel cell is included as the prescribed site.

The 17th aspect of the present invention is a program for making a computer function as

an impedance computation instrument for computing an impedance corresponding to a prescribed portion of a fuel cell of a fuel cell system from a signal obtained by superposing the alternating current on the direct current according to the 10th or the 11th aspect of the present invention, and

a diagnosis instrument in which when in comparison of the impedance with an impedance as computed under a previously determined standard operation condition, an abnormality is present in the prescribed portion of the fuel cell, whether a cause of the abnormality of the prescribed portion resides in any one or plural prescribed sites constituting the fuel cell system is determined by using the comparison result.

The 18th aspect of the present invention is a recording medium for recording the program according to the 17th aspect of the present invention, which can be processed by a computer.

The 19th aspect of the present invention is a diagnosis site specifying method of a fuel cell system for specifying a prescribed site, which is used for the failure diagnosis method of a fuel cell system according to the 1st aspect of the present invention against a fuel cell system including a power generation section having a fuel cell, an oxidizer gas feed section for feeding an oxidizer gas into the power generation section for the purpose of power generation of the fuel cell, and a hydrogen gas feed section for feeding a hydrogen gas into the power generation section for the purpose of power generation of the fuel cell, the method including:

a step for computing impedances of plural prescribed portions of the fuel cell of the fuel cell system from a signal obtained by superposing an alternating current on a direct current as generated from the fuel cell system,

a step for specifying at least one of a specific site within the hydrogen gas feed section, a specific site within the oxidizer gas feed section and a specific site within the power generation section as an operation site, and

a step for changing the operation condition to make the fuel cell system act and at that time, observing whether the impedance of any one of the plural prescribed portions of the fuel cell is changed, thereby specifying the operation site as the prescribed site.

In light of the above, according to the present invention, in a failure diagnosis method of the foregoing fuel cell system, it becomes possible to specify which portion of the fuel cell system which is a subject necessary for the diagnosis should be used.

### Advantages of the Invention

The present invention has such an advantage that in operating a fuel cell system, the site of a failure which is a cause of a power generation abnormality can be rapidly detected.

### BRIEF DESCRIPTION OF THE DRAWINGS

[FIG. 1]

FIG. 1 is an explanatory graph in which impedances as measured by sweeping a frequency of an embodiment of the present invention are plotted.

[FIG. 2]

FIG. 2 is an explanatory view of an equivalent circuit to express an impedance of a cell of an embodiment of the present invention.

[FIG. 3]

FIG. 3 is a graph to show an S/N ratio versus an amplitude of an alternating current in an embodiment of the present invention.

[FIG. 4(a)]

FIG. 4(a) is an explanatory graph to express a relation between an impedance and a frequency of an embodiment of the present invention.

[FIG. 4(b)]

FIG. 4(b) is an explanatory view of an equivalent circuit of an impedance of an embodiment of the present invention.

[FIG. 4(c)]

FIG. 4(c) is an explanatory view of an equivalent circuit of an impedance of an embodiment of the present invention.

[FIG. 4(d)]

FIG. 4(d) is an explanatory view of an equivalent circuit of an impedance of an embodiment of the present invention.

[FIG. 5(a)]

FIG. 5(a) is a constitutional view of a fuel cell system of an embodiment of the present invention.

[FIG. 5(b)]

FIG. 5(b) is a constitutional view of a fuel cell system of an embodiment of the present invention.

[FIG. 6(a)]

FIG. 6(a) is a drawing to show a flow chart for explaining a diagnosis method of an embodiment of the present invention.

[FIG. 6(b)]

FIG. 6(b) is a drawing to show a flow chart for explaining a diagnosis method of an embodiment of the present invention.

[FIG. 6(c)]

FIG. 6(c) is a drawing to show a flow chart for explaining a diagnosis method of an embodiment of the present invention.

[FIG. 6(d)]

FIG. 6(d) is a drawing to show a flow chart for explaining a diagnosis method of an embodiment of the present invention.

[FIG. 7(a)]

FIG. 7(a) is a graph to explain separation of the site of a failure using a characteristic profile in an embodiment of the present invention.

[FIG. 7(b)]

FIG. 7(b) is a graph to explain separation of the site of a failure using a characteristic profile in an embodiment of the present invention.

[FIG. 7(c)]

FIG. 7(c) is a graph to explain separation of the site of a failure using a characteristic profile in an embodiment of the present invention.

[FIG. 7(d)]

FIG. 7(d) is a graph to explain separation of the site of a failure using a characteristic profile in an embodiment of the present invention.

[FIG. 8]

FIG. 8 is a table to show a chart for explaining the site of diagnosis of an embodiment of the present invention.

[FIG. 9]

FIG. 9 is a graph to show a change with time of cell voltage in Example 1 and Comparative Example of the present invention.

[FIG. 10]

FIG. 10 is a table to show a chart for expressing the result of diagnosis after 5,000 hours in Example 1 of the present invention.

[FIG. 11]

FIG. 11 is a table to show a chart for expressing the result of diagnosis after 10,000 hours in Example 1 of the present invention.

[FIG. 12]

FIG. 12 is a constitutional view to show a cross-section of a hydrogen generation device of an embodiment of the present invention.

### DESCRIPTION OF REFERENCE NUMERALS AND SIGNS

4a: Impedance in sweeping frequencies

4b: Impedance expressed by equivalent circuit b

4c: Impedance expressed by equivalent circuit c

4d: Impedance expressed by equivalent circuit d

71: Cell voltage of Example 1

72: Cell voltage of Comparative Example

### DETAILED DESCRIPTION OF THE INVENTION

First of all, prior to explaining a failure diagnosis method or the like of a fuel cell system of the present embodiment, in order to enable one to understand it more easily, a principle of the present invention is described.

A single cell which constitutes a fuel cell is constituted of a hydrogen ion conducting electrolyte membrane and an electrode aligned in every side thereof and is of a so-called polymer electrolyte type.

The single cell is constituted by providing one pair of separator plates having a gas passage for feeding a fuel gas into one of the electrodes and discharging it therefrom and a gas passage for feeding an oxygen-containing gas into the other electrode and discharging it therefrom. Incidentally, the electrode into which the fuel gas is fed is an anode, and the electrode into which the oxygen-containing gas is fed is a cathode.

One fuel cell stack is constituted by stacking several tens to several hundreds of such a single cell.

The impedance of the single cell is made up of an impedance of the anode, an impedance of the cathode, an impedance of the electrolyte membrane, and a contact resistance of each of the constitutional elements.

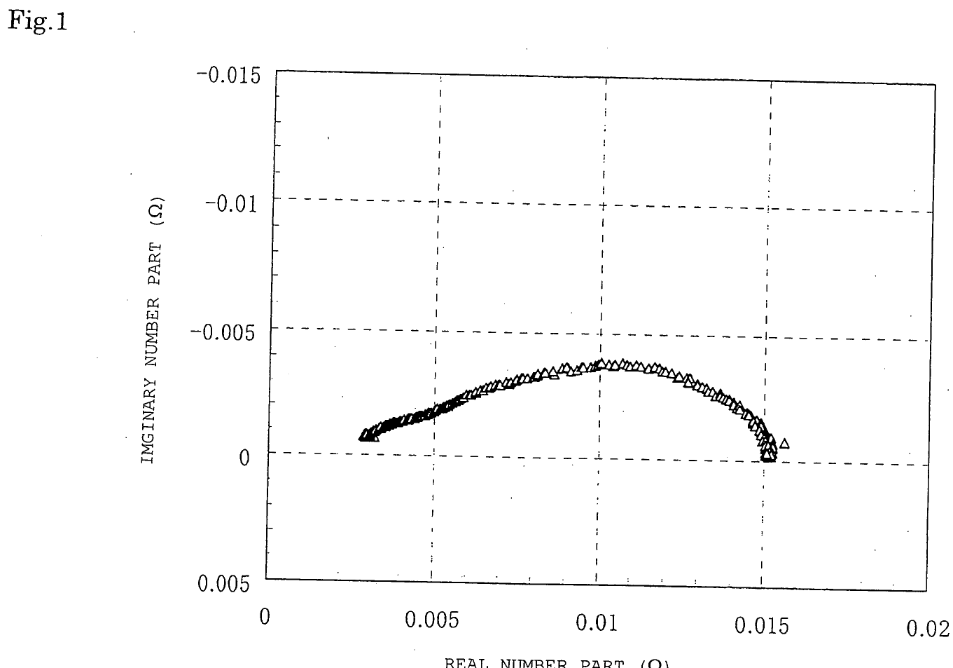

In the embodiment of the present invention, plots of an imaginary number part versus a real number part of impedance of a typical single cell are shown in FIG. 1 which is an explanatory graph in which impedances as measured by sweeping a frequency of an alternating current for superposition as described later are plotted.

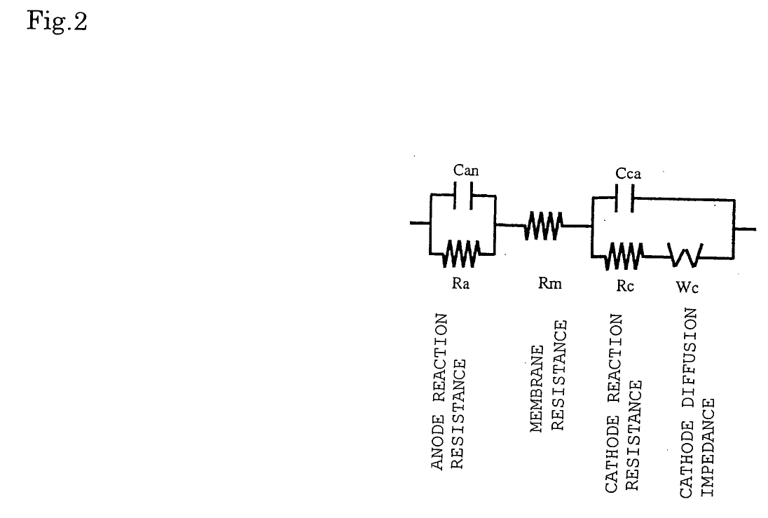

Incidentally, the inventor of the present invention has found that as an equivalent circuit to indicate the behavior of this impedance, an equivalent circuit to indicate an impedance of the single cell of an embodiment of the present invention as shown in FIG. 2 has the highest precision.

Here, a measurement method of an impedance characteristic is described.

An alternating current with a frequency f having a micro amplitude of not more than approximately 10% of a current amplitude value of a direct current to be taken out from a fuel cell is superposed on the direct current of the fuel cell and then taken out.

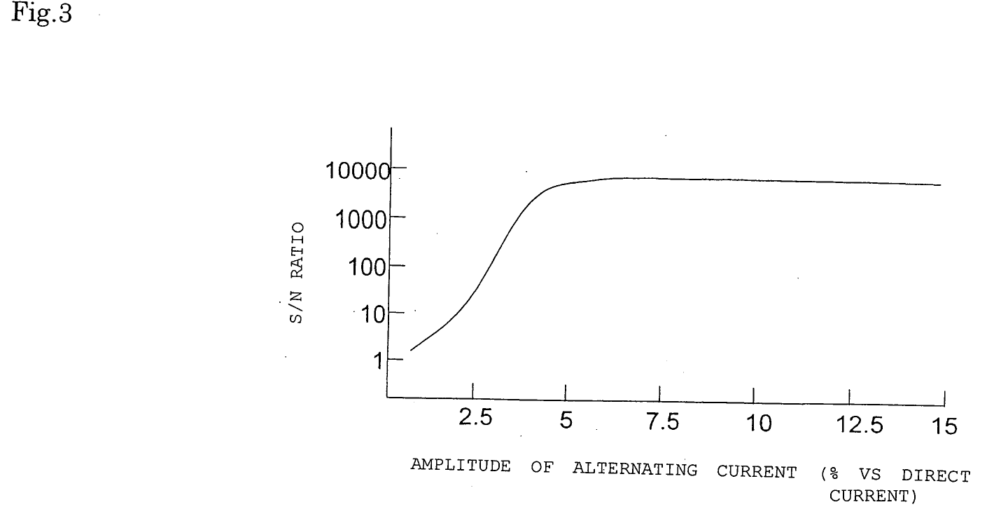

Then, an impedance is computed from amplitudes and phases of an alternating current component of cell voltage and an alternating current component of cell current as measured at that time. A ratio of signal to noise (S/N ratio) is improved such that the amplitude of the alternating current to be superposed is large. However, as shown in FIG. 3, when the amplitude of the alternating current exceeds 5% of the direct current, the S/N ratio is saturated and even when the amplitude is further increased, the S/N ratio is no longer improved.

On the other hand, in the case of a fuel cell, since the current which flows through the cell is accompanied with the movement of electric charges due to a chemical reaction, when the amplitude of the alternating current is increased, the amount of reaction versus the amount of feed gas (usage rate of gas) fluctuates. Usually, when the alternating current having an amplitude of not more than 10% of the direct current is impressed, the fluctuation of the usage rate of gas is small and does not influence the measured values. However, when it exceeds 10%, an influence of the fluctuation of the usage rate of gas cannot be neglected so that an error in the measured values is generated.

Hence, the amplitude of the alternating current to be impressed is desirably from approximately 5% to 10% of the direct current.

When a complex impedance of the equivalent circuit is defined as Z and its real number part and imaginary number part are defined as Zr and Zi, respectively, the following is held.
Z=Zr−jZi (Equation 1)
(In the expression, j represents an imaginary number unit; hereinafter the same.)

Furthermore, when an alternating current component of cell voltage of the single cell at the time of measurement is defined as a complex number E and its real number part and imaginary number part are defined as Er and Ei, respectively; and when an alternating current component of cell current of the single cell is defined as a complex number I and its real number part and imaginary number part are defined as Ir and Ii, respectively, the following are held.
E=Er−jEi
I=Ir−jIi
Z=E/I=(Er−jEi)/(Ir−jIi) (Equation 2)

Thus, the complex impedance can be computed from E and I as measured at the time of taking out an alternating current with a frequency f.

In addition, by sweeping the frequency f of the alternating current to be taken out from approximately 0.1 Hz to approximately 1,000 Hz, a complex impedance at each frequency is computed in the same manner.

Then, by plotting on a complex plane in which the abscissa represents the real number part Zr and the ordinate represents -Zi marked with a minus symbol for the imaginary number part Zi, a Cole-Cole plot as shown in FIG. 1 is prepared.

In the case of an equivalent circuit which is a parallel circuit made up of one pair of a resistance and a condenser, the Cole-Cole plot is in a semi-circular shape with a fixed radius having central points on the abscissa (so-called Cole-Cole circular arc law).

In the case of an equivalent circuit having resistances (resistance values) Rm, Ra and Rc, condensers (capacity values) Ca and Cc and a Warburg impedance Wc as shown in FIG. 2, the Cole-Cole plot is in a shape having three circular arcs superposed thereon.

Complex impedances at various frequencies f are measured, and values of the components (Rm, Ra, Rc, Ca, Cc and Wc) of the equivalent circuit as characteristics of a prescribed portion of the present invention which are fit to the complex impedances are calculated.

In respective physical meanings of the components of the equivalent circuit, Rm represents a resistance value of the electrolyte membrane; Ra represents an anode reaction resistance; Rc represents a cathode reaction resistance; Ca represents an anode double layer capacity; Cc represents a cathode double layer capacity; and Wc represents a cathode diffusion impedance, respectively.

Here, Wc represents a finite-length Warburg impedance represented by (Equation 3).
Wc=Rw·tan h(jTω)^{P}/(jTω)
P=0.5,T=L²/D (Equation 3)

In (Equation 3), L represents an effective diffusion thickness; D represents a diffusion coefficient; and ω represents an angular velocity. Also, Rw represents a cathode diffusion resistance and is equal to Wc when ω→0. The cathode diffusion resistance Rw is hereinafter used as the component indicating the diffusion impedance.

When the frequency is changed minutely as far as possible, the precision for calculating the component is higher. However, if only four Rm, Ra, Rc and Rw are calculated, the foregoing four resistance values can be approximately calculated by measuring real number components of a complex impedance in at four frequencies at minimum.

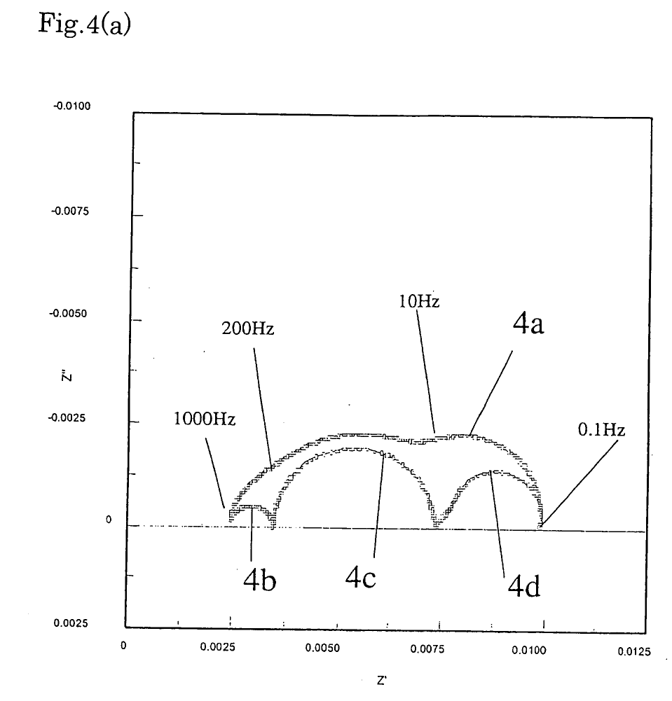

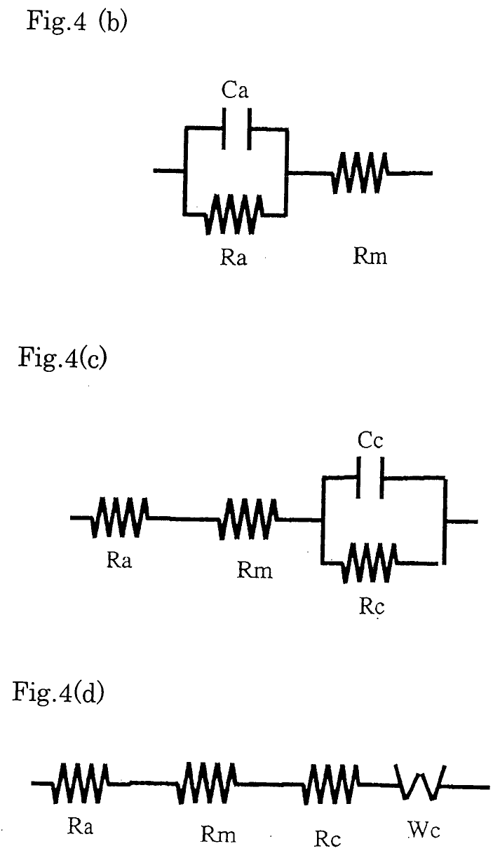

That is, as shown in FIGS. 4(a) to 4(d), the real number component of a complex impedance at a high frequency (for example, 1,000 Hz) is substantially equal to Rm; the real number component at 200 Hz is (Rm+Ra); the real number component at 10 Hz is (Rm+Ra+Rc); and the real number component at 0.1 Hz is (Rm+Ra+Rc+Rw).

Next, changes in the resistance value in the equivalent circuit were examined by changing the operation condition of a single cell, thereby obtaining the following result.

In the case of changing the usage rate of air which is an oxygen-containing gas, Rw chiefly changed.

In the case of changing the concentration of hydrogen in the fuel gas, Ra chiefly changed.

Also, in the case of changing the temperature distribution of the single cell, Rm chiefly changed.

In other words, it is noted that the change of each of the conditions for operating the fuel cell is related to a change of each of the components when the fuel cell is likened as an equivalent circuit and that a specific condition is corresponding to a specific component.

From this, the following is found out. That is, in a fuel cell system, by specifying each of a constitutional element necessary for changing the usage rate of air to be fed into the fuel cell, a constitutional element necessary for changing the concentration of hydrogen in the fuel gas to be fed into the fuel cell and a constitutional element necessary for changing the temperature distribution of the fuel cell as a prescribed site, it can be considered that the change of the resistance value of each of the components in the equivalent circuit reflects the operation state of such a prescribed site.

Accordingly, when the operation condition in the foregoing prescribed site is changed, in the case where a deviation of an actual operation state from an operation condition as set up for the fuel cell system, namely an abnormality, is generated, by observing how the resistance value of each of the components of the equivalent circuit changes, it becomes possible to identify where such an abnormality is generated in the foregoing prescribed site level.

Concretely, an impedance of the single cell under a previously determined operation condition, for example, a rated condition is measured, and a rated value of the component of the equivalent circuit is stored.

Then, by comparing the value of the component of the equivalent circuit as determined by measuring the impedance at the time of changing the operation condition with a value as stored at the time of rating, a change of the value of the component of the equivalent circuit is judged. In the case where there is a component showing an abnormal change, since it is possible to know the change of that component is corresponding to what change of the operation condition of the prescribed site, the site of a failure of the fuel cell system can be specified at the same time of discovering the abnormality.

The embodiment of the present invention is described below in more detail.

### EMBODIMENT

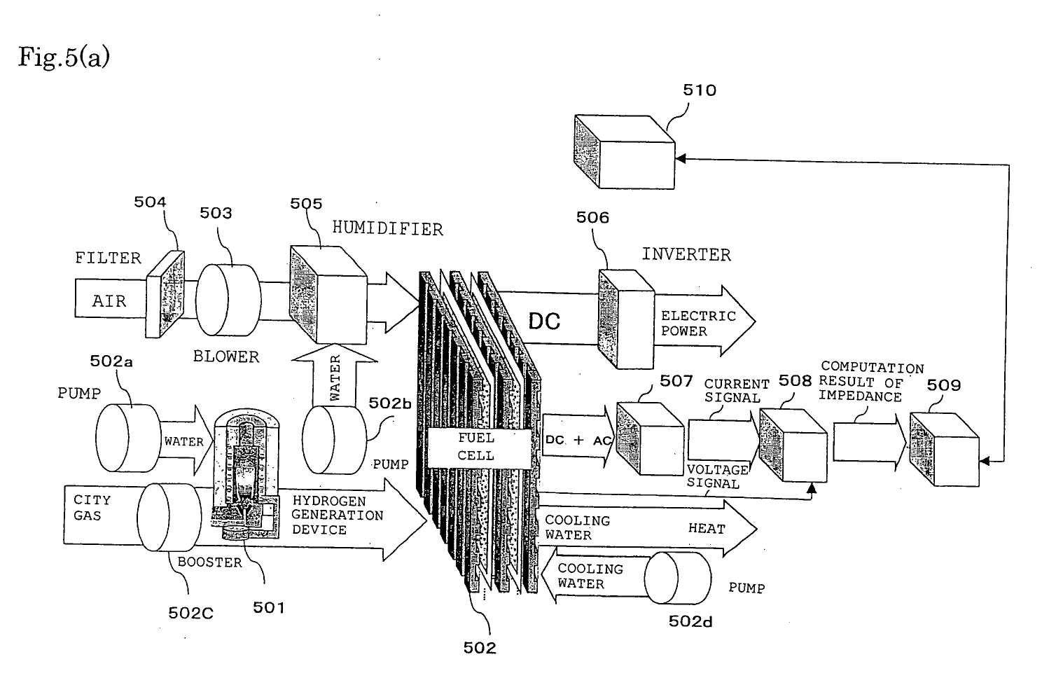

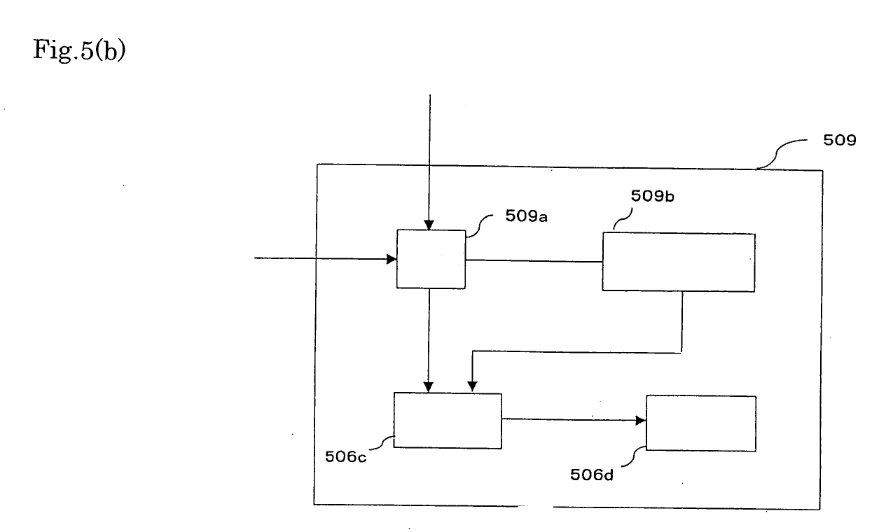

First of all, a fuel cell system and a constitution of a failure diagnosis device of an embodiment of the present invention are described while referring to FIG. 5(a) which is a constitutional view of a fuel cell power generation system and a failure diagnosis device of the fuel cell power generation system of the present embodiment.

The fuel cell power generation system of the present embodiment is a fuel cell power generation system for adding water to a city gas; reforming the mixture by a hydrogen generation device 501 to prepare a hydrogen-containing gas; feeding it as a fuel gas into an anode (not shown) of a fuel cell 502; and humidifying air and feeding it into a cathode (not shown), thereby achieving power generation. Besides, the fuel cell power generation system is provided with a pump 502a for feeding water into the hydrogen generation device 501; a booster 502c for pressurizing the city gas; a blower 503 for introducing air as an oxidizer gas into the fuel cell 502; a cooling water pump 502d for feeding cooling water into the fuel cell 502; a filter 504 for removing dusts and other impurities from air as introduced by the blower 503; a humidifier 505 for humidifying air which has passed through the filter 504; a pump 502b for feeding water into the humidifier 505; an inverter 506 for converting a direct current (DC) from the fuel cell into an alternating current power; and a control instrument 510 for controlling the action of each of these sections.

Furthermore, the failure diagnosis device of the fuel cell system is provided with the inverter 506; an alternating current source 507 for selectively receiving a direct current from the fuel cell and superposing an alternating current thereon; an impedance computing instrument 508 for computing an impedance from a signal having an alternating current and a direct current superposed thereon; and a diagnosis instrument 509 for judging an abnormality of the fuel cell of the fuel cell system by using information from the control instrument 510 and the impedance as computed by the impedance computing instrument 508, thereby determining by what constitutional portion of the fuel cell system that abnormality is caused.

Incidentally, in the foregoing constitution, a reformer, a burner for heating the reformer, the pump 502a and the booster 502c constitute a hydrogen gas feed section of the present invention. Furthermore, the blower 503, the pump 502b, the filter 504 and the humidifier 505 constitute an oxidizer gas feed section of the present invention. Moreover, the pump 502d and the fuel cell 501 constitute a power generation section of the present invention.

Next, FIG. 5(b) shows a constitution of the diagnosis instrument 509. The diagnosis instrument 509 includes a characteristic profile preparation instrument 509a for receiving inputs of the impedance computation result and parameters of the action condition of each of the sections of the fuel cell system to be inputted from the control instrument 510 and preparing a characteristic profile of each of the sections therefrom; a memory 509b for storing the prepared characteristic profile; a diagnosis main body section 509c for comparing the characteristic profile with the impedance computation result, thereby specifying the presence or absence of an abnormality and the site of a failure; and a display section 509d for displaying the diagnosis result and the like. Incidentally, the memory 509 is also able to store each of data from the diagnosis main body section 509c, data from the control instrument 510 and the impedance computation result. Further, the display section 509d may be realized by a conventionally known instrument such as speakers and displays so far as it is an instrument capable of displaying the diagnosis result and the like by voices, screen images, or the like.

The hydrogen generation device 501 is constituted of a reformer, a burner for heating the reformer, a carbon monoxide remover for removing carbon monoxide from a reformed gas as outputted from the reformer, and so on and is a device for undergoing a reformation reaction of methane in the city gas and water within the reformer, thereby producing a reformed gas composed mainly of hydrogen and carbon dioxide. Incidentally, though details of on example of the constitution of the hydrogen generation device 501 are described in each of the Examples, the constitution of the hydrogen generation device may be a conventionally known constitution. In summary, it should be construed that the present invention is not limited to a specific constitution of the hydrogen generation device.

Usually, at the time of power generation, a load current of the fuel cell 502 is converted into an alternating current by flowing through the inverter 506 and then taken out into the outside. Heat as generated at the time of power generation is taken out into the outside with the aide of cooling water.

At the time of failure diagnosis, a load current of the fuel cell is flown through the alternating current source 507 instead of flowing it through the inverter 506; an alternating current signal is superposed on the load current of a direct current; and the impedance computation instrument 508 measures a voltage to be detected from a voltage measurement terminal as connected to a cell of the fuel cell 502 and a complex impedance from the current flowing through the cell and inputs the measurement result into the diagnosis instrument 509. At this time, the parameters of the operation condition of a specified portion which is made to act at the time of failure diagnosis are inputted into the diagnosis instrument 509 from the control instrument 510. In the diagnosis instrument 509, the characteristic profile preparation instrument 509a form a characteristic profile from a change of the impedance corresponding to the parameter change of the operation condition from the foregoing two inputs as a characteristic profile and stores it in the memory 509a.

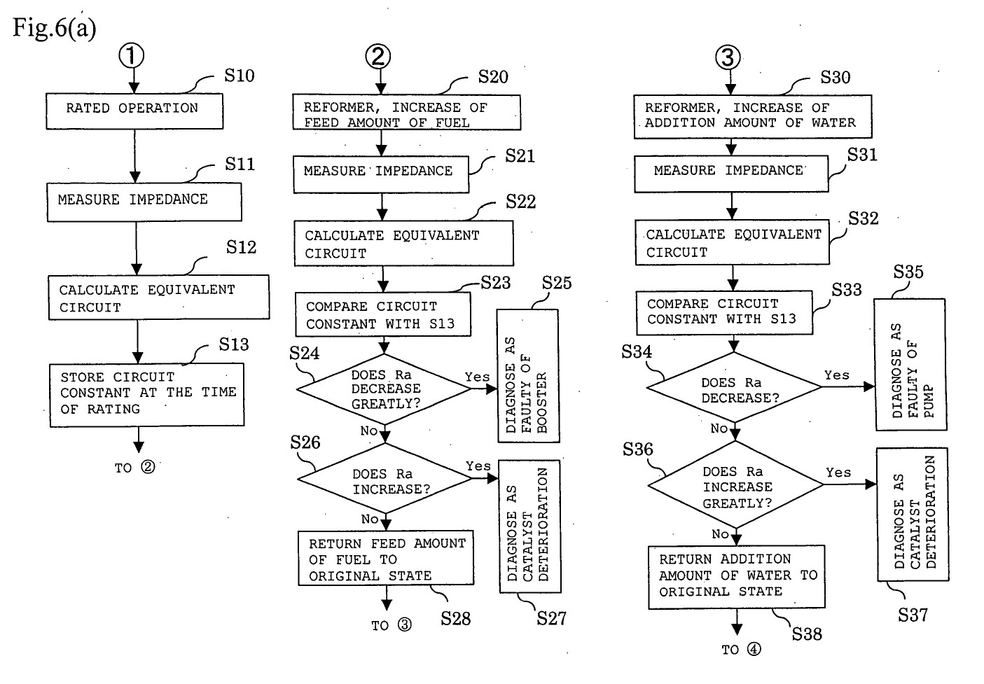

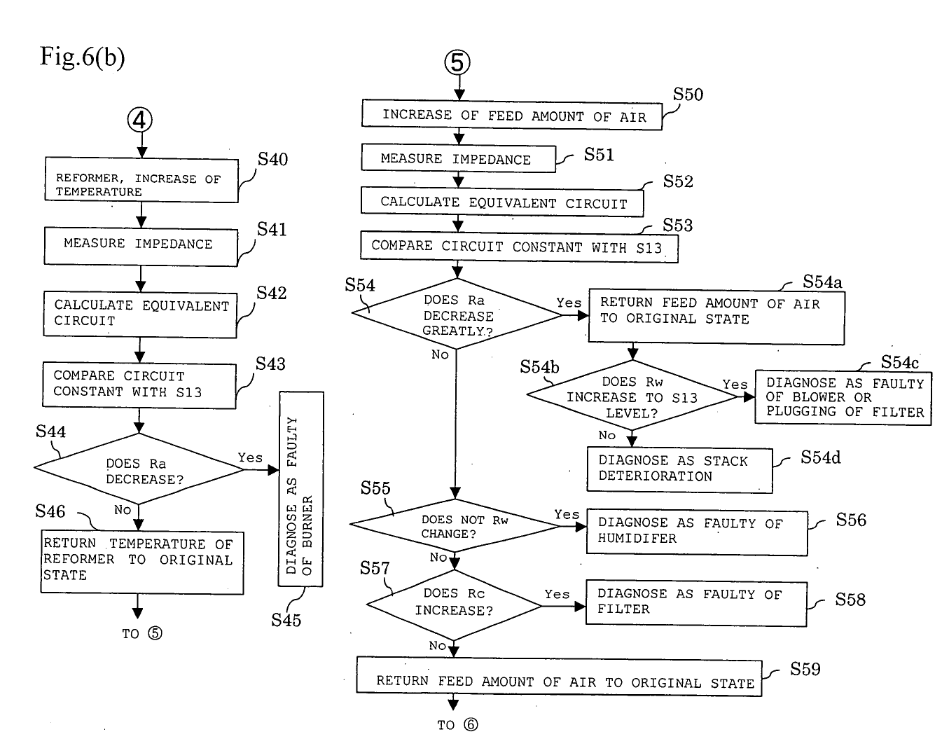

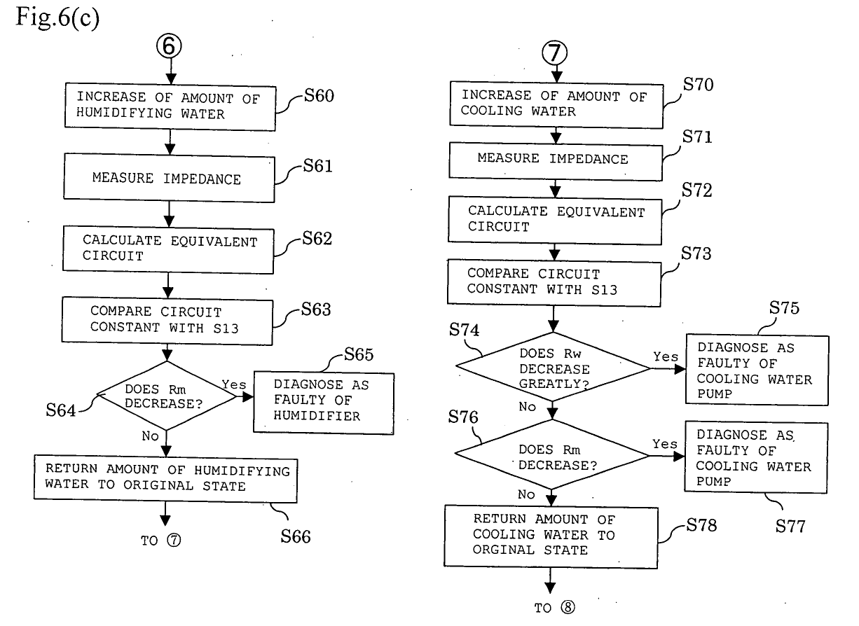

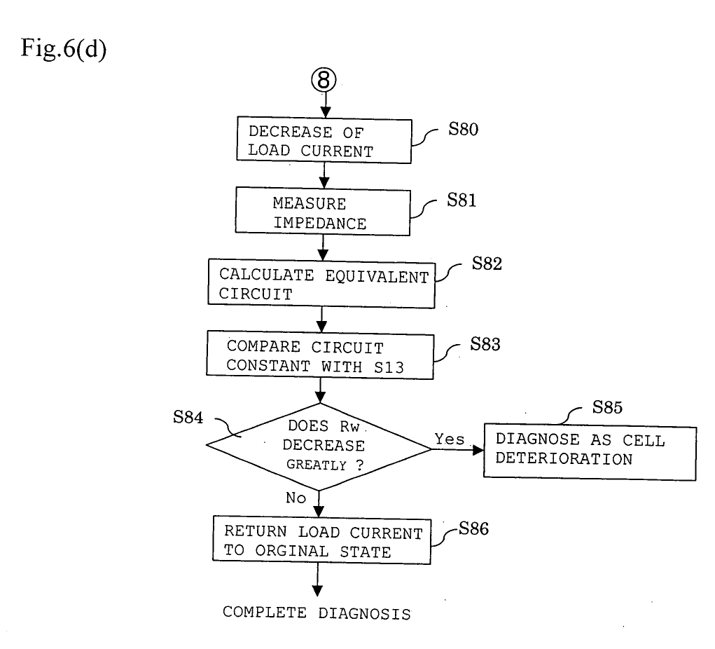

Next, a failure diagnosis method of the fuel cell power generation system of the present embodiment is described, and also, the failure diagnosis device of a fuel cell power generation system and an embodiment of the fuel cell power generation system are described while referring to the respective flow charts of FIGS. 6(a) to 6(d).

First of all, the fuel cell system is subjected to power generation under the rated operation condition as a previously determined standard operation condition of the present invention, and an impedance at that time is measured, thereby determining a value of each of the components of the equivalent circuit. As shown in FIG. 6(a), concretely, the fuel cell power generation system is subjected to rated operation (S10); the impedance computation instrument 508 measures an impedance of the fuel cell 502 on that occasion (S11); the equivalent circuit of FIG. 2 is calculated on the basis of this (S12); and the circuit constants at the time of rating (Ra, Rc, Rw and Rm) which are the components of this equivalent circuit are stored in the memory 509b of the diagnosis instrument 509 (S13). Incidentally, the circuit coefficients at the time of rating are corresponding to the impedances of the characteristic profile of the invention of the present application.

Next, the operation condition of each of the sections constituting the hydrogen gas feed section, the oxidizer gas feed section and the power generation section of the fuel cell power generation system is changed. By changing the operation condition of each of the sections, air as an oxidizer gas and a hydrogen gas as a fuel gas into the fuel cell 501 and the temperature distribution of the fuel cell 501 are changed. These changes appear as changes in the respective circuit constants Ra, Rc, Rw and Rm of the equivalent circuit. Incidentally, each of the sections which change the operation condition is corresponding to the specified site of the present invention.

Accordingly, by changing the operation condition of each of the sections constituting the hydrogen gas feed section, the oxidizer gas feed section and the power generation section and observing how the resistance value in the equivalent circuit changes against such a change, it is possible to diagnose and determine the presence or absence of an abnormality of the hydrogen gas feed section, the oxidizer gas feed section and the power generation section.

(Diagnosis on the Basis of Hydrogen Gas Feed Section)

First, changing the operation condition of the hydrogen gas feed section imparts changes to the concentration of hydrogen in the fuel gas. Accordingly, by paying attention to a change of Ra as a circuit constant, it is possible to judge the presence or absence of an abnormality of the hydrogen gas feed section. An explanation thereof is given below.

The control instrument 510 controls the booster 502c so as to increase the feed amount of fuel into the reformer, namely the feed amount of city gas (S20); the impedance computation instrument 508 measures an impedance of the fuel cell 502 after increasing the feed amount of fuel (S21); the equivalent circuit of FIG. 2 is calculated on the basis of this (S22); and the circuit constants (Ra, Rc, Rw and Rm) as diagnosis impedances, which are the components of this equivalent circuit, are calculated (S22), thereby comparing (S23) with the circuit coefficients at the time of rating as already stored in the memory 509b.

When the feed amount of fuel into the reformer is increased as compared with that of the time of rating, in general, Ra becomes slightly small. On the other hand, when an abnormality is present, Ra takes a change different from this. Whether or not this different change is related to an experientially obtained abnormality of a prescribed site of the hydrogen gas feed section is judged. The relation between such a change of Ra from the rating and an abnormality of a prescribed site of the hydrogen gas feed section (such as the reformation section and the booster 502) is experientially obtained and is previously stored in the memory 509b of the diagnosis instrument 509. Using this, the diagnosis main body section 509c judges whether or not the change of Ra is related to the abnormality of the prescribed site.

First of all, in the case where Ra has become greatly small, since it is thought that the usage rate Uf of fuel is abnormally large at the time of rating, whether or not Ra has become greatly small is first judged (S24). As a cause that Ra becomes greatly small, it is assumed that an ability of the booster 502c for pressurizing the city gas is lowered so that an original ability is not produced, resulting in occurrence of a shortage of the fuel. The diagnosis instrument 509 makes the judgment on the basis of this (S25). When the booster 502c is adjusted or exchanged on the basis of the diagnosis result, the repair is completed.

On the other hand, in the case where it is judged that Ra has not become greatly small, whether or not Ra has further increased is judged (S26). This is because as a cause that Ra increases, it is thought that in the reformer in the hydrogen generation device 501, the conversion of methane into hydrogen is lowered at the time of rating. Since a lowering of the conversion is caused by catalyst deterioration, the diagnosis instrument 509 makes the judgment of catalyst deterioration on the basis of this (S27). It is possible to take a countermeasure such as exchange of the reformer on the basis of the diagnosis result.

In the case where it is judged that Ra has not increased, too, since it is thought at least on the basis of this diagnosis that an abnormality which is caused by the reformer or the booster 502c as the prescribed site of the present invention is not present, the feed amount of fuel is returned to the original state (S28); and by changing an action condition in a next specified site, the diagnosis is continued.

The control instrument 510 controls the pump 502a so as to increase the addition amount of water to the reformer, namely the feed amount of water to be added to the city gas as a fuel (S30); the impedance computation instrument 508 measures an impedance of the fuel cell 502 after increasing the addition amount of water (S31); and the equivalent circuit of FIG. 2 and the circuit constants (Ra, Rc, Rw and Rm) as components thereof are newly calculated on the basis of this (S32) and compared with the circuit coefficients at the time of rating as already stored in the memory 509b (S33).

When the addition amount of water to the reformer is increased as compared with that of the time of rating, in general, Ra becomes slightly large. On the other hand, when an abnormality is present, Ra takes a change different from this. Whether or not this different change is related to an experientially obtained abnormality of a prescribed side of the hydrogen gas feed section is judged.

First of all, in the case where Ra has become small, since it is thought that a steam/carbon ratio (S/C) in the fuel is not proper at the time of rating, whether or not Ra has become small is judged (S34). In the case where Ra has become small, it is considered that S/C is not proper. As a cause of this, it is assumed that the pump 502a for feeding water causes a failure. The diagnosis instrument 509 makes the judgment on the basis of this (s35). When the pump 502a is adjusted or exchanged on the basis of the diagnosis result, the repair is completed.

On the other hand, in the case where it is judged that Ra has not become small, whether or not Ra has further increased is judged (S36). This is because as a cause that Ra increases greatly, it is thought that in the reformer in the hydrogen generation device 501, the conversion of methane into hydrogen is lowered at the time of rating. Since a lowering of the conversion is caused by catalyst deterioration, the diagnosis instrument 509 makes the judgment of catalyst deterioration on the basis of this (S37). It is possible to take a countermeasure such as exchange of the reformer on the basis of the diagnosis result.

In the case where it is judged that Ra has not increased greatly, too, since it is thought at least on the basis of this diagnosis that an abnormality which is caused by the reformer or the pump 502a as the prescribed site of the present invention is not present, the addition amount of water is returned to the original state (S38); and by changing an action condition in a next specified site, the diagnosis is continued.

Next, as shown in FIG. 6(b), likewise S20 to S23, the control instrument 510 controls the burner so as to increase the temperature of the reformer; and the equivalent circuit and the circuit constants (Ra, Rc, Rw and Rm) as the diagnosis impedances of the present invention are calculated on the basis of this and compared with the circuit coefficients at the time of rating as already stored in the memory 509b (S40 to S42)

When the temperature of the reformer is increased as compared with that of the time of rating, in general, Ra has become slightly large. On the other hand, in the case where Ra becomes small, since it is thought that the conversion is lowered due to a lowering of the temperature of the reformer at the time of rating, whether or not Ra has become small is judged (S44). In the case where Ra has become small, it is thought that the conversion of methane into hydrogen in the reformed is lowered. However, since this is caused due to a failure of the burner for heating the reformer, the diagnosis instrument 509 makes the judgment of a failure of the burner on the basis of this (S45). It is possible to take a countermeasure such as cleaning or exchange of the burner on the basis of the diagnosis result.

On the other hand, in the case where it is judged that Ra has not become small, since it is thought at least on the basis of this diagnosis that an abnormality which is caused by the burner as the prescribed site of the present invention is not present, the temperature of the reformer is returned to the original state (S46).

In light of the above, by paying attention to the change of Ra, the presence or absence of an abnormality of the hydrogen gas feed section was judged.

(Diagnosis on the Basis of Oxidizer Gas Feed section)

Secondly, changing the operation condition of the oxidizer gas feed section imparts changes to the usage rate and humidity of air and so in the fuel gas to be fed into the fuel cell 502. Accordingly, by paying attention to changes of Rw, Rc and Rm as circuit constants, the presence or absence of an abnormality of the oxidizer gas feed section is judged. An explanation thereof is given below.

Likewise S20 to S23, the control instrument 510 controls the blower 503 so as to increase the feed amount of air into the fuel cell 502 (for example, by increasing an output or revolution number of the blower 503); and the equivalent circuit and the circuit constants (Ra, Rc, Rw and Rm) as the diagnosis impedances of the present invention are calculated on the basis of this and compared with the circuit coefficients at the time of rating as already stored in the memory 509b (S50 to S53)

When the feed amount of air into the fuel cell 502 is increased as compared with that of the time of rating, in general, Ra becomes slightly small. On the other hand, when an abnormality is present, Rw takes a change different from this. Whether or not this different change is related to an experientially obtained abnormality of a prescribed site of the oxidizer gas feed section as previously stored in the memory 509b is judged.

First of all, in the case where Rw has become greatly small, since it is thought that flooding of the cell which constitutes the fuel cell 501 occurs at the time of rating, whether or not Rw has become greatly small is first judged (S54). In the case where it is judged that Rw has become greatly small, the control instrument 510 receives this result from the diagnosis instrument 509 and undergoes control so as to return the feed amount of air into the fuel cell 502 to the original state (S54a) Here, the actions of S50 to S53 are repeated to obtain Rw, and whether or not that value has reached a level as obtained in S13 (S54b). In the case where Rw has reached the level, it is assumed that the flooding is caused by the matter that the feed amount of air to be actually fed into the fuel cell 502 becomes lower than a value as set up by the control and by a lowering of the ability of the blower 503 or filter plugging of the filter 504. The diagnosis instrument 509 makes the judgment on the basis of this (S54c). It is possible to take a countermeasure on the basis of the diagnosis result by adjusting or exchanging the blower 503c or cleaning or exchanging the filter 504.

On the other hand, in the case where Rw has not reached the level as obtained in S13, it is assumed that the wettability of the single cell of the fuel cell 502 increases. The diagnosis instrument 509 makes the judgment on the basis of this (S54d). It is possible to take a countermeasure on the basis of the diagnosis result by stack exchange of the fuel cell 502.

Furthermore, in the case where it is judged that Rw has not become greatly small in S54, whether or not Rw has changed before and after the control for increasing the feed amount of air is then judged (S55). In the case where Rw has not changed, it is thought that the single cell of the fuel cell 502 is dried at the time of rating and is in the dry-up state. It is assumed that this is caused by a lowering of a humidification ability of the humidifier 505. The diagnosis instrument 509 makes the judgment on the basis of this (S56). It is possible to take a countermeasure on the basis of the diagnosis result by adjusting or exchanging the humidifier 505 or the pump 502b.

In addition, in the case where it is judged that Rw has changed before and after the control for increasing the feed amount of air in S55, whether or not Rc has increased is then judged (S57). In the case where Rc has increased, it is thought that impurities such as NOx in air are incorporated into the cell. It is assumed that this is caused by a lowering of a removal ability of impurities of the filter 504. The diagnosis instrument 509 makes the judgment of a failure of the filter on the basis of this (S58). It is possible to take a countermeasure such as cleaning or exchange of the filter 504 on the basis of the diagnosis result.

On the other hand, in the case where it is judged that Rc has not become large, since it is thought at least on the basis of this diagnosis that an abnormality which is caused by the blower 503, the humidifier 505, the pump 502b or the filter 504 as the prescribed site of the present invention is not present, the feed amount of air is returned to the original state (S59); and by changing an action condition in a next specified site, the diagnosis is continued.

Next, as shown in FIG. 6(c), likewise S20 to S23, the control instrument 510 controls the pump 502b so as to increase the amount of humidifying water, namely the amount of water to be fed into the humidifier 505; and the equivalent circuit and the circuit constants (Ra, Rc, Rw and Rm) as the diagnosis impedances of the present invention are calculated on the basis of this and compared with the circuit coefficients at the time of rating as already stored in the memory 509b (S60 to S63)

Even when the amount of humidification of water is increased as compared with that of the time of rating, in general, Rm does not change. On the other hand, when Rm has become small, it is thought that the single cell of the fuel cell 502 is dried at the time of rating and is in the dry-up state. It is assumed that this is caused by a lowering of a humidification ability of the humidifier 505. The diagnosis instrument 509 makes the judgment on the basis of this (S65). It is possible to take a countermeasure on the basis of the diagnosis result by adjusting or exchanging the humidifier 505 or the pump 502b.

On the other hand, in the case where it is judged that Rm has not become small, since it is thought at least on the basis of this diagnosis that an abnormality which is caused by the humidifier 505 or the pump 502b as the prescribed site of the present invention is not present, the amount of humidifying water is returned to the original state (S66).

In light of the above, by paying attention to the changes of Rw, Rc and Rm, the presence or absence of an abnormality of the oxidizer gas feed section was judged.

(Diagnosis on the Basis of Power Generation Section)

Thirdly, changing the operation condition of the power generation section imparts changes to the temperature and current and so on of the fuel cell 502. Accordingly, by paying attention to changes of Rw and Rm as circuit constants, the presence or absence of an abnormality of the power generation section is judged. An explanation thereof is given below.

Likewise S20 to S23, the control instrument 510 controls the pump 502d so as to increase the amount of cooling water of the fuel cell 502, namely the feed amount of water; and the circuit constants (Ra, Rc, Rw and Rm) as the equivalent circuit and diagnosis impedances of the present invention are calculated on the basis of this and compared with the circuit coefficients at the time of rating as already stored in the memory 509b (S70 to S73)

In the single cell of the fuel cell 502, the temperature is controlled by cooling water. The temperature distribution within the single cell depends upon the amount of cooling water so that the larger the amount of cooling water, the smaller the temperature distribution is. When the amount of cooling water is increased as compared with that of the time of rating, in general, Rw becomes slightly small. On the other hand, in the case where Rw has become greatly small, it is thought that the temperature distribution of the single cell is large at the time of rating and that flooding of the cell which constitutes the fuel cell 501 occurs. Then, whether or not Rw has become greatly small is judged (S74) In the case where it is judged that Rw has become greatly small, it is considered that flooding occurs. This is because the amount of cooling water which is actually fed into the fuel cell 502 becomes lower than a value as set up by the control and by a lowering of the ability of the pump 502d. The diagnosis instrument 509 makes the judgment on the basis of this (S75). It is possible to take a countermeasure on the basis of the diagnosis result by adjusting or exchanging the pump 502d.

On the other hand, in the case where Rw has not become greatly small, whether or not Rm has become small is judged (S76). In the case where it is judged that Rm has become small, it is thought that the temperature distribution of the single cell is large at the time of rating and that dry-up occurs in a part of single cell. This is because the amount of cooling water which is actually fed into the fuel cell 502 becomes lower than a value as set up by the control and by a lowering of the ability of the pump 502d. The diagnosis instrument 509 makes the judgment on the basis of this (S77). It is possible to take a countermeasure on the basis of the diagnosis result by adjusting or exchanging the pump 502d.

On the other hand, in the case where it is judged that Rm has not become small, since it is thought at least on the basis of this diagnosis that an abnormality which is caused by the pump 502d as the prescribed site of the present invention is not present, the amount of cooling water is returned to the original state (S78); and by changing an action condition in a next specified site, the diagnosis is continued.

Next, as shown in FIG. 6(d), likewise S20 to S23, the control instrument 510 controls the alternating current source 507 so as to decrease the load current which the fuel cell 502 outputs; and the equivalent circuit and the circuit constants (Ra, Rc, Rw and Rm) as the diagnosis impedances of the present invention are calculated on the basis of this and compared with the circuit coefficients at the time of rating as already stored in the memory 509b (S80 to S83).

When the load current to be taken out from the fuel cell 502 is decreased as compared with that of the time of rating, in general, Rw becomes slightly small. On the other hand, in the case where Rm has become greatly small, it is thought that the single cell of the fuel cell 502 is in a state of flooding at the time of rating. The, whether or not Rm has become greatly small is judged (S84) In the case where it is judged that Rm has become greatly small, it is considered that flooding occurs. As a cause of this, it is assumed that the wettability due to deterioration of the single cell increases. The diagnosis instrument 509 makes the judgment on the basis of this (S85). It is possible to take a countermeasure on the basis of the diagnosis result by adjusting or exchanging the fuel cell 502.

On the other hand, in the case where it is judged that Rm has not become small, since it is thought at least on the basis of this diagnosis that an abnormality which is caused by the fuel cell 502 as the prescribed site of the present invention is not present, the load current is returned to the original state (S86).

In light of the above, by paying attention to the changes of Rw and Rm, the presence or absence of an abnormality of the power source section was judged.

(Diagnosis of Abnormality of Fuel Cell per se)

In light of the above, the actions for diagnosing the presence or absence of an abnormality in the prescribed sites of the hydrogen gas feed section, the oxidizer gas feed section and the power source section have been described on the basis of the changes of the impedance values as respective circuit coefficients which constitute the equivalent circuit of the fuel cell 502 as caused by changing the operation conditions of the respective specified sites of the hydrogen gas feed section, the oxidizer gas feed section and the power source section. On the other hand, as causes of the changes of the impedances in the equivalent circuit, in addition to the foregoing changes of the specified sites, there is enumerated deterioration of the fuel cell 502 per se. In the case where the deterioration of the fuel cell 502 contributes to the whole of the impedances (Ra, Rc, Rw and Rm) of the equivalent circuit, the changes of the impedance values as obtained by the measurement must be separated into, for example, one which is caused due to the temperature change of the reformer as a specified site or one based on the deterioration of the fuel cell 502.

In the present embodiment, as already described, in the diagnosis instrument 509, the characteristic profile preparation instrument 509a prepares changes of impedances corresponding to the changes of parameters of the operation condition from impedance values as inputted from the impedance computation instrument 508 and parameters to indicate the operation condition of the fuel cell power generation system as obtained from the control instrument 510 as a characteristic profile and stores it in the memory 509b.

The failure diagnosis method according to the present invention is to grasp influences by the changes of parameters of the operation condition against the changes of impedances in advance and observe how the impedances are changed at the time of changing the operation condition, thereby specifying the site of a failure.

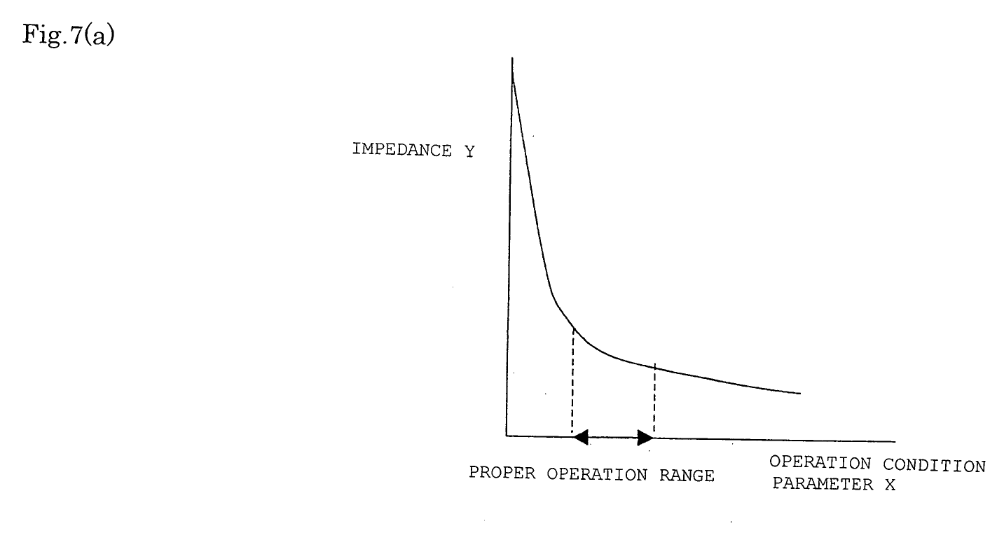

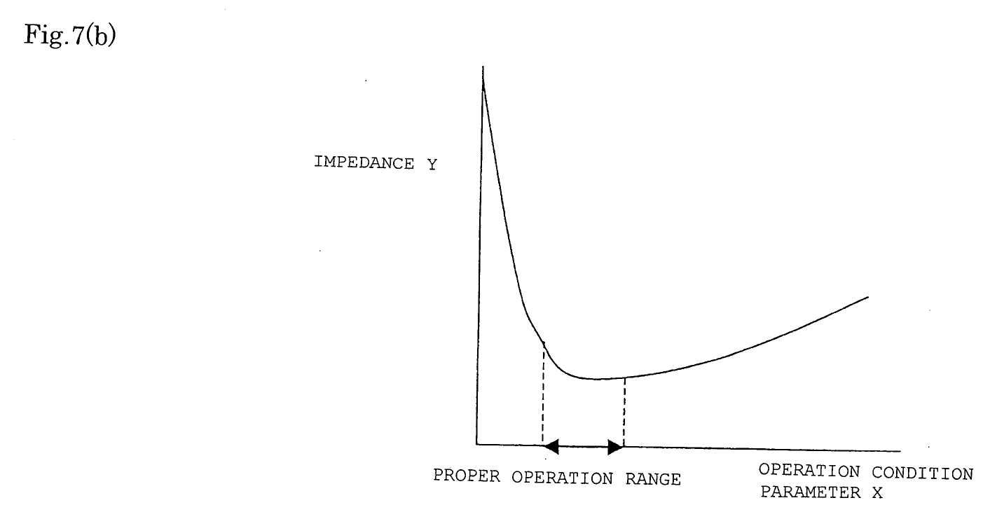

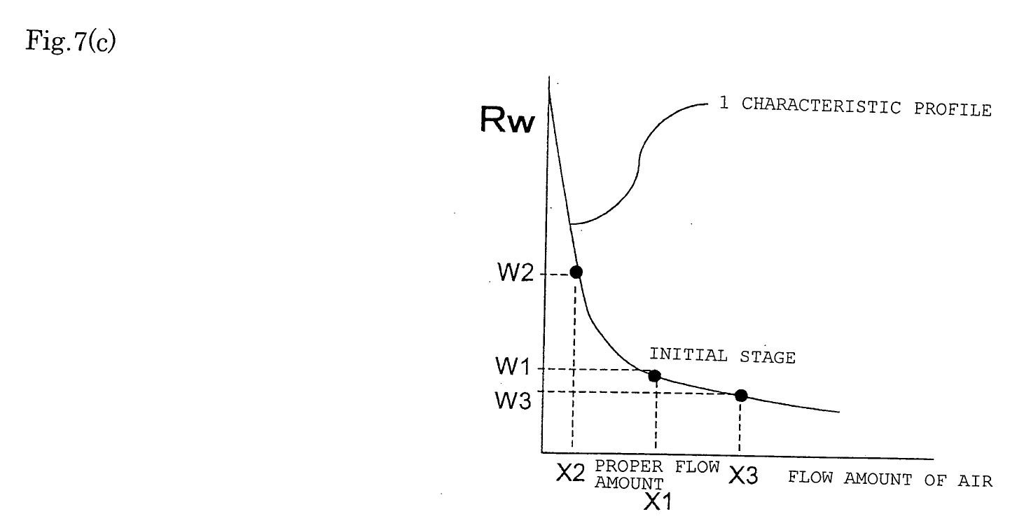

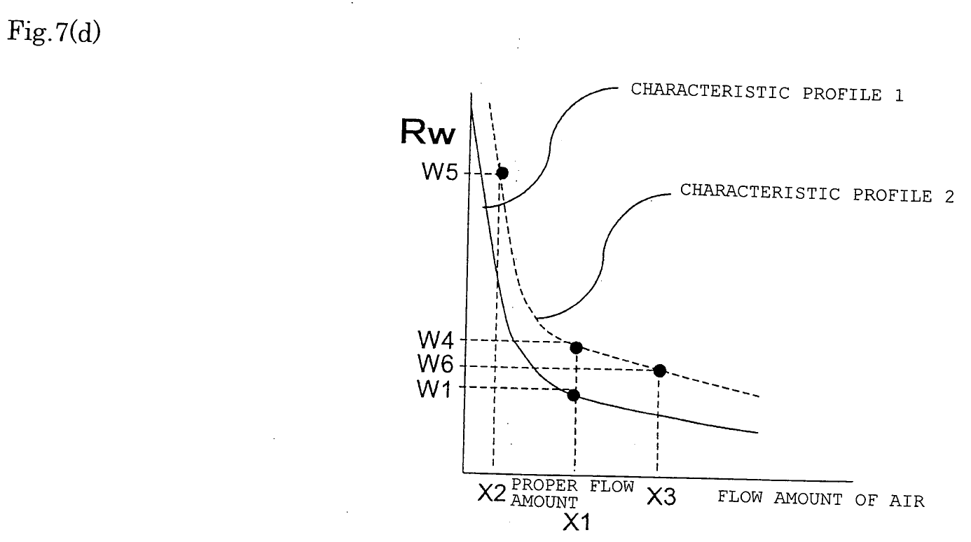

A relation between the operation condition and the impedance is typically in a relation as shown in FIG. 7(a). That is, an impedance component Y changes versus an operation condition parameter X. The “operation condition parameter X” as referred to herein means a physical amount for controlling the fuel cell and includes, for example, the feed amount of air and the feed amount of cooling water. The “impedance component Y” as referred to herein means a circuit constant resulting from analyzing the impedance by the equivalent circuit, and a circuit constant which changes mainly by X is defined as Y. For example, in the case where X is defined as the feed amount of air, Y is corresponding to Rw.

In general, the operation condition parameter X is set up such that Y becomes as small as possible. However, in many cases, energy is required for the purpose of making X large, and to make X large thoughtlessly is disadvantageous in the case of thinking of the entire efficiency of the fuel cell system. Then, taking into account an improvement of the amount of power generation by making Y small and an improvement of the amount of energy consumption by making X small, a proper operation range is determined such that an efficiency as the entire system is improved. In many cases, the relation between the impedance Y and the operation condition parameter X has a bending point as shown in FIG. 7(a), and a proper operation range exists in the vicinity of that bending point.

Furthermore, there may be the case where the impedance Y versus the operation condition parameter X has a minimum point as shown in FIG. 7(b). In this case, a proper operation range is set up in the vicinity of the minimum point. This is corresponding to, for example, the feed amount of fuel into the fuel cell or the addition amount of water to the fuel.

As one example, the change of an impedance value in the case of changing the operation condition of the blower 503 which is a specified site constituting the oxidizer gas feed section as shown in FIG. 6(b) is described with reference to FIG. 7(c). The change of impedance versus the feed amount of air is shown as a characteristic profile 1. When control is carried out in a proper flow amount X1, the Rw component of impedance is defined as W1. Nevertheless the blower for feeding air is deteriorated and the control corresponding to X1 is carried out, in the case where air was actually fed only in a flow amount corresponding to X2, the impedance should indicate W2. At this time, when control is carried out so as to increase the flow amount of air and the actual flow amount of air changes from X2 to X1, the impedance decreases greatly from W2 to W1. In this way, in the case where the impedance Rw decreases greatly, it is suggested that an abnormality was present in the air feed system such as the blower.

On the other hand, in the case where the blower has not caused deterioration, a proper flow amount X1 of air is fed into the fuel cell, and the impedance is W1 as it is. At this time, in the case where control is carried out so as to increase the flow amount of air and the actual amount of air changes from X1 to X3, since the impedance decreases merely minutely from W1 to W3, it is noted that an abnormality was not present in the air feed system such as the blower.

In the failure diagnosis, since not only a peripheral device of the fuel cell such as the blower causes a failure but also the fuel cell itself is deteriorated with time, it is difficult to diagnose the site of a failure. According to the failure diagnosis method of the present invention, it is possible to separate an abnormality as caused due to deterioration of the fuel cell itself and an abnormality as caused due to a failure of the peripheral device. An example in which deterioration of the fuel cell is added to the impedance change of FIG. 7(c) is described with reference to FIG. 7(d).

When control is carried out in a proper flow amount X1, an initial impedance is defined as W1. When the fuel cell is deteriorated, an impedance change is shown as a characteristic profile 2. When control is carried out in a proper flow amount X1, the impedance becomes W4. In the case where air was actually fed only in a flow amount corresponding to X2 in spite of the blower for feeding air is deteriorated and the control corresponding to X1 is carried out, the impedance should indicate W5. At this time, when control is carried out so as to increase the flow amount of air and the actual flow amount of air changes from X2 to X1, the impedance decreases greatly from W5 to W4. In this way, in the case where the impedance Rw decreases greatly, it is suggested that an abnormality was present in the air feed system such as the blower.

On the other hand, in the case where the blower does not cause deterioration, a proper flow amount X1 of air is fed into the fuel cell, and the impedance is W4 as it is. At this time, in the case where control is carried out so as to increase the flow amount of air and the actual amount of air changes from X1 to X3, since the impedance decreases merely minutely from W4 to W6, it is noted that an abnormality was not present in the air feed system such as the blower.

In this way, the presence or absence of an abnormality of the peripheral device can be detected regardless of the presence or absence of deterioration of the fuel cell itself.

In light of the above, in the fuel cell power generation system of the present embodiment, by dividing portions which constitute the fuel cell power generation system into the hydrogen gas feed section, the oxidizer gas feed section and the power generation section, changing the operation condition of a specified site of each of the sections and comparing an impedance of the fuel cell corresponding thereto with an impedance at the time of rated operation, it is possible to diagnose the presence or absence of an abnormality in every prescribed site of the hydrogen gas feed section, the oxidizer gas feed section and the power generation section. It is possible to realize a system provided with an entire diagnosis function at low costs without particularly providing an exclusive sensor for every section of the hydrogen gas feed section, the oxidizer gas feed section and the power generation section.

Incidentally, in the fuel cell power generation system of the present invention, though the system made up of a single single cell as the fuel cell 502 is representatively shown, by connecting a fuel cell stack in which plural single cells are stacked in place of the single cell, it is also possible to measure an impedance of the whole of the fuel cell stack.

Furthermore, in the foregoing respective diagnoses, though in FIG. 5, the diagnosis is automatically carried out using the diagnosis instrument 509, a person who makes the diagnosis may make the diagnosis using impedances as the computation result of the impedance computation instrument 508. Further, though the utilization of values of the comparison result of each of the components of impedances has been carried out by comparing the size of computation values or comparing a difference in the size thereof, the size of a ratio of the computation values may be utilized. It is only required that the diagnosis as referred to in the present invention is one made based on the size of values resulting from quantification of the comparison result of impedances, but it should not be depended on a method of the treatment after the quantification.

Furthermore, with respect to the foregoing respective diagnoses, while the case where only one site of a failure of the fuel cell power generation system is assumed has been exemplified, the diagnosis may be made based on the assumption of a plural number of sites of a failure. In this case, it is also possible to rapidly respond to the failure. Moreover, needless to say, as described previously, the site of a failure of the present invention may be each of the instruments as shown in FIG. 5 and alternatively, in the case where the system is composed of plural constitutional elements including a reformer, a catalyst and a burner as in the hydrogen generation device 501, the system may specify any one or plural sites of those constitutional elements.

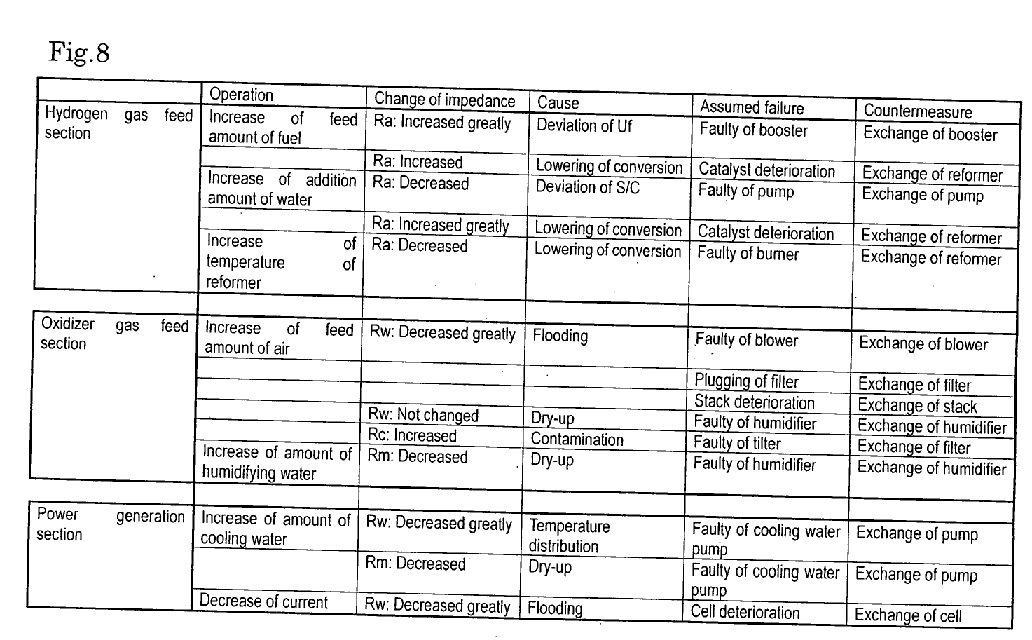

Furthermore, while the foregoing respective diagnoses have been shown as a series of the flow charts as shown in FIGS. 6(a) to 6(d), they can be shown as a table in random order as shown in FIG. 8. So far as the diagnosis can be carried out for every item in full, the respective operations may be carried out in random order without following the foregoing flow charts. Moreover, in the case where it is intended to carry out the diagnosis regarding any one of the hydrogen gas feed section, the oxidizing gas feed section and the power generation section, an operation regarding only the corresponding portion may be carried out.

Next, the Examples of the present invention are described in detail.

### EXAMPLE 1

First of all, the preparation of the fuel cell 502 is described.

A gas diffusion layer was prepared in the following method. A carbon paper (TGPH-060, manufactured by Toray Industries, Inc.) was immersed with a dispersion of poly-tetrafluoroethylene (LUBRON LDW-40, manufactured by Daikin Industries, Ltd.) in a dry weight of 10% by weight and then subjected to a water-repellent treatment by heating at 350° C. using a hot air dryer.

In addition, a polymer-containing conducting layer made up of a carbon powder and a fluorine resin was formed. That is, a dispersion as prepared by mixing DENKA BLACK, manufactured by Denki Kagaku Kogyo K. K. as the carbon powder with a dispersion of polytetrafluoroethylene (LUBRON LDW-40, manufactured by Daikin Industries, Ltd.) as the fluorine resin in a dry weight of 30% by weight was coated on the foregoing carbon paper which had been subjected to a water-repellency treatment and heated at 350° C. by using a hot air dryer, thereby preparing a gas diffusion layer containing a polymer-containing conducting layer.

Next, an electrolyte membrane-electrode assembly (MEA) was prepared in the following method. 10 g of water was added to 10 g of a material resulting from supporting 50% by weight of a platinum particle having an average particle size of about 30 Å angstroms on a conducting carbon power (TEC10E50E, manufactured by Tanaka Kikinzoku Kogyo), which was then mixed with 55 g of a 9% by weight ethanol solution of a hydrogen ion conducting polymer electrolyte (FLEMION, manufactured by Asahi Glass Co., Ltd.) to prepare a catalyst paste. This paste was coated on a polypropylene film by bar coating using a wire bar and dried to form an oxidizer electrode side catalyst layer. The amount of coating of the catalyst layer was adjusted such that the content of platinum was 0.3 mg per 1 cm².

10 g of water was added to 10 g of a material resulting from supporting a platinum-ruthenium alloy on a conducting carbon power (TEC61E54, manufactured by Tanaka Kikinzoku Kogyo), which was then mixed with 50 g of a 9% by weight ethanol solution of a hydrogen ion conducting polymer electrolyte (FLEMION, manufactured by Asahi Glass Co., Ltd.) to prepare a catalyst paste. This paste was coated on a polypropylene film by bar coating using a wire bar and dried to form a fuel electrode side catalyst layer. The amount of coating of the catalyst layer was adjusted such that the content of platinum was 0.3 mg per 1 cm².

Each of the catalyst layer-provided polypropylene films was cut into 6 cm squares; a hydrogen ion conducting polymer electrolyte membrane (GORE-SELECT, manufacture by Japan Gore-Tex Inc., thickness: 30 μm) was interposed by two pairs of the foregoing catalyst layer-provided polypropylene films such that the catalyst layers were faced inwardly each other; and after hot pressing at 130 ° C. for 10 minutes, the polypropylene films were removed to obtain a catalyst layer-provided polymer electrolyte membrane.

MEA was formed by using the catalyst layer-provided polymer electrolyte membrane.

On the other hand, a graphite plate was subjected to cutting processing to provide a gas passage and a cooling water passage, thereby preparing a separator plate. MEA was interposed by one pair of the separator plates to constitute a single cell.

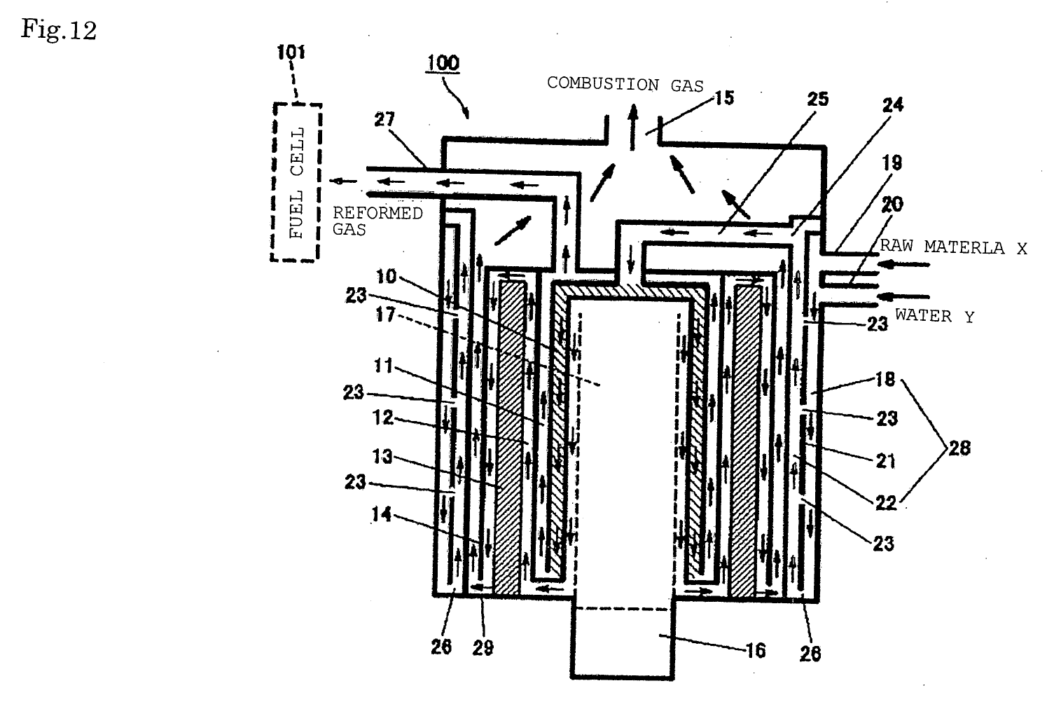

The thus prepared single cell was used for the fuel cell 502 to prepare a fuel cell power generation system having the constitution of FIG. 5. Incidentally, the hydrogen generation device 501 was prepared according to a method as described in JP-A-2003-252604. A cross-sectional view of the hydrogen generation device is illustrated in FIG. 12. As illustrated in FIG. 12, the hydrogen generation device 501 of the present embodiment is provided with a burner 16 for generating a combustion gas and a cylindrical combustion chamber 17 which is provided above this burner 16. A cylindrical reformer 10 is provided coaxially with the combustion chamber 17 in the peripheral side of the combustion chamber 17. The reformer 10 accommodates a catalyst layer having a steam reforming catalyst filled therein, and a raw material gas is subjected to a steam reforming reaction to generate a reformed gas.

Incidentally, the fuel cell 502 is provided on the outside of the hydrogen generation device 501, and the fuel cell system of the present invention is constituted of the hydrogen generation device 501 and fuel cell 502. The reformed gas as generated in the reformer 10 is discharged from a reformed gas discharge port 27 and fed into the fuel cell 502.

Furthermore, a cylindrical reformed gas passage 11 for introducing the reformed gas as generated in the reformer 10 into the reformed gas discharge port 27 and a cylindrical combustion gas passage 12 into which the combustion gas as generated in the burner 16 in the peripheral side of the reformed gas passage 11 flows are respectively provided coaxially with the combustion chamber 17 in the peripheral side of the reformer 10. The combustion gas passage 12 is made up of a passage as partitioned by a cylindrical heat insulating material 13 and a cylindrical body 14 and constituted so as to introduce the combustion gas towards a combustion gas discharge port 15.

In addition, a cylindrical evaporation chamber 28 is provided coaxially with the combustion chamber 17 in the peripheral side of the combustion gas passage 12 and on the outermost periphery of the hydrogen generation device 501. This evaporation chamber 28 is constituted of a cylindrical first evaporation chamber 18 and a second evaporation chamber 22 as provided partitioning from the first evaporation chamber 18 via a cylindrical partition 21. Here, the second evaporation chamber 22 is positioned in the side of the combustion gas passage 12, and the first evaporation chamber 18 is positioned in the peripheral side of the second evaporation chamber 22, namely on the outermost periphery of the hydrogen generation device 501 via the partition 21. In an upper part of the first evaporation chamber 18, a raw material inlet 19 for feeding a raw material X containing a compound constituted of at least carbon and hydrogen into the device and a water inlet 20 for feeding water Y into the same are formed. Incidentally, examples of the compound constituted of at least carbon and hydrogen include hydrocarbons such as methane, ethane and propane, a city gas, a natural gas, alcohols such as methanol, kerosene, and LPG (liquefied petroleum gas). Incidentally, a city gas is employed in FIG. 5. Furthermore, in an upper part of the second evaporation chamber 22, a steam outlet 24 which is an outlet of steam as generated in the evaporation chamber 28 is provided. This steam outlet 24 is connected to the reformer 10 via a steam feed pipe 25. Accordingly, the steam as discharged from the steam outlet 24 is fed into the reformer 10 via the steam feed pipe 25.

Furthermore, the filter 504 is constituted of MC HONEYCOMB and HEPA FILTER as manufactured by Nagase & Co., Ltd. and is used to remove dust, NOx and SOx in air.

A reformed gas (hydrogen: 80%, carbon dioxide: 20%, carbon monoxide: 20 ppm, dew point: 65° C.) prepared by adding water to the city gas and reformed by the hydrogen generation device 501 was fed into the fuel electrode side, and air as humidified such that the dew point was 70° C. was fed into the oxygen electrode side, thereby undergoing power generation at a usage rate of fuel of 80% and a usage rate of oxygen of 40% in a current density of 200 mA/cm².

The cooling water was adjusted so as to have a temperature of 70° C. in the inlet side of the single cell and 72° C. to 75° C. in the outlet side thereof, respectively.

A voltage of the single cell was 0.75 V.

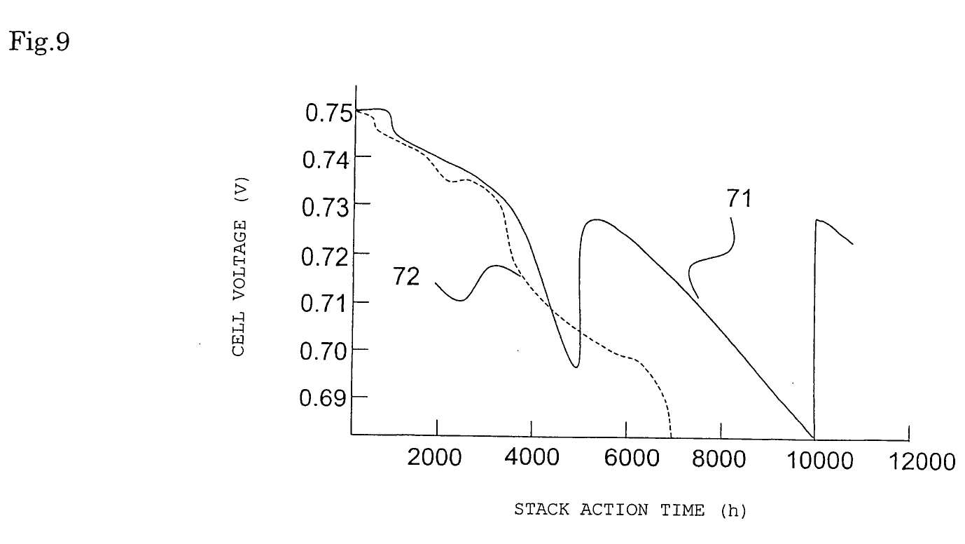

FIG. 9 shows a change with time of cell voltage. The cell voltage was gradually lowered with time, and after a lapse of 5,000 hours after starting the operation, the cell voltage was lowered to not more than 0.70 V.

A load current was applied by changing the connection from an inverter to an impedance analyzer, thereby measuring a complex impedance at 1,000 Hz, 200 Hz, 10 Hz and 0.1 Hz, respectively.

The impedance computation instrument 508 was constituted of a combination of a frequency response analyzer (SI1250, manufactured by SOLARTRON) and an electron load (Fuel Cell Test System SERIES 890B, manufactured by SCRIBNER).

The load current was a current resulting from superposing a sine wave of ±10 mA/cm² on a direct current of 200 mA/cm².

By defining a real number component of the complex impedance at 1,000 Hz as Rm, a real number component at 200 Hz as (Rm+Ra), a real number component at 10 Hz as (Rm+Ra+Rc) and a real number component at 0.1 Hz as (Rm+Ra+Rc+Rw), respectively, each of Rm, Ra, Rc and Rw at the time of rating was calculated.

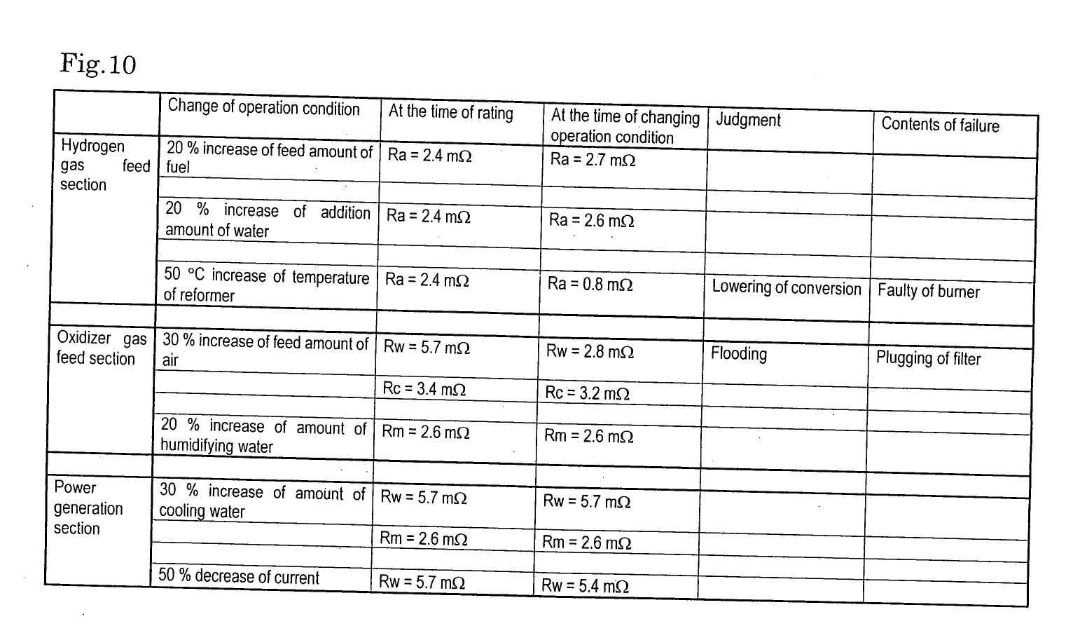

Impedances were measured in the same manner by changing the operation condition as shown in FIG. 10. FIG. 10 shows resistance values before and after changing the operation condition and judgments. It was noted from this that flooding of the cathode took place and that the inspection revealed plugging of the filter 504. Thus, the filter 504 was exchanged.

Furthermore, it was noted that a lowering of the conversion occurred due to failing of the burner 16. Thus, cleaning of the burner 16 was carried out.

Thereafter, the power generation was again started under the rated condition. As a result, the cell voltage was recovered to 0.73 V.

In addition, the power generation was continued. As a result, the cell voltage of the fuel cell 502 was gradually lowered with time, and after a lapse of 10,000 hours of the operation time in total, the cell voltage was lowered to not more than 0.68 V. FIG. 9 shows a change with time of cell voltage.

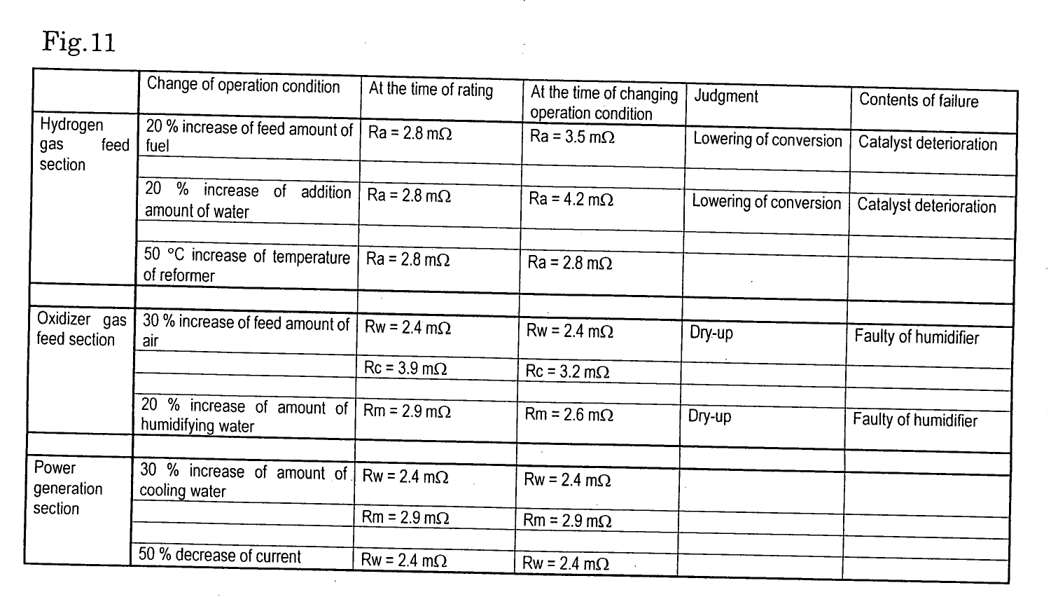

Impedances were again measured at the time of changing the rated condition and the operation condition. FIG. 11 shows resistance values before and after changing the operation condition and judgments. It was noted from this that faulty of the humidifier 505 and catalyst deterioration of the reformer took place. Thus, the humidifier 505 and the reformer 10 were exchanged. Thereafter, the power generation was again started under the rated condition. As a result, the cell voltage was recovered to 0.73 V.

### EXAMPLE 2

A single cell was constituted in the same manner as in Example 1, and by using this single cell, a fuel cell power generation system of FIG. 5 was prepared in the same manner as in Example 1.

An operation was carried out in the same manner as in Example 1, and it was confirmed that the cell voltage was 0.75 V.

When an ability of the cooling water pump 502d was lowered to 70%, the cell voltage was lowered to 0.72 V.

The ability was returned to 100%, and impedances were again measured and compared. As a result, after increasing the amount of cooling water, Rw greatly decreased from 5.3 mΩ to 2.5 mΩ so that a shortage of the ability of the cooling water pump 502d at the time of rating could be confirmed.

### COMPARATIVE EXAMPLE

A fuel cell power generation system having the same constitution as in Example 1 was prepared.

An operation was carried out in the same manner as in Example 1, and the power generation was continued without undergoing the impedance computation and repair on the way. As a result, as shown in FIG. 9, the power generation voltage of the fuel cell 502 was lowered, and after a lapse of 7,000 hours after starting the power generation, the voltage was abruptly lowered so that the power generation became impossible.

In comparison of the foregoing Examples 1 to 2 with the Comparative Example, it has become clear that according to the present invention, the site of a failure of the fuel cell system can be specified and that by undergoing rapid repair thereby, the fuel cell system can be kept in an optimum state so that the power generation of the fuel cell can be stably kept for a long period of time.

Incidentally, the program according to the present invention is a program for executing a function of the whole or a part of the foregoing failure diagnosis device of the fuel cell system of the present invention by a computer and may be a program which acts in cooperation with a computer.

Furthermore, the present invention is concerned with a medium carrying thereon a program for executing a function of the whole or a part of the whole or a part of the instrument of the foregoing failure diagnosis device of a fuel cell system of the present invention by a computer and may be a medium which can be read by a computer and in which the read program executes the foregoing instrument in cooperation with the foregoing computer.

Incidentally, the “part of instrument” as referred to in the present invention means some instruments among plural instruments or means a part of function or a part of action of a single instrument.

Also, the “part of device” as referred to in the present invention means some instruments among plural instruments, or means a part of instrument of a single device or means a part of function of a single instrument.

Also, a recording medium having a program of the present invention recorded thereon, which can be read by a computer, is included in the present invention.

Also, an embodiment for use of the program of the present invention may be an embodiment in which a program is recorded on a recording medium which can be read by a computer acts in cooperation with the computer.

Also, an embodiment for use of the program of the present invention may be an embodiment in which a program is transmitted in a transmission medium, is read by a computer and acts in cooperation with the computer.

Also, the recording medium includes ROM and so on, and the transmission medium includes transmission media such as Internet, light, radio waves, acoustic waves, and so on.

Also, the foregoing computer of the present invention is not limited to a pure hardware such as CPU but may be one including a firmware, OS and a peripheral device.

Incidentally, as described previously, the constitution of the invention may be realized in a software fashion or may be realized in a hardware fashion.

### INDUSTRIAL APPLICABILITY

The failure diagnosis method of a fuel cell system and the failure diagnosis device of the present invention are able to rapidly specify a cause of a power generation abnormality of a fuel cell and to efficiently undergo repair and therefore, are useful.

1. A failure diagnosis method of a fuel cell system, which includes a step for computing an impedance in a prescribed portion of a fuel cell of a fuel cell system from a signal obtained by superposing an alternating current on a direct current generated from the fuel cell system under a certain operation condition, wherein
when in comparison of the impedance with an impedance as computed under a previously determined standard operation condition, an abnormality is present in the prescribed portion of the fuel cell, whether a cause of the abnormality of the prescribed portion resides in any one or plural prescribed sites constituting the fuel cell system is determined by using the comparison result; and
the determination is to separate whether the cause of the abnormality of the prescribed portion resides in the fuel cell per se which the fuel cell system has or the prescribed sites other than the fuel cell.

2. (canceled)

3. The failure diagnosis method of a fuel cell system according to claim 1, comprising the steps of:
performing the determination by using a corresponding relation between an operation condition of each prescribed site of the fuel cell system and an impedance of each prescribed portion of the fuel cell under the standard operation condition as a characteristic profile,
as the certain operation condition, changing the operation condition of the prescribed site more greatly than the standard operation condition and comparing a diagnosis impedance as measured corresponding to the change with an impedance of the characteristic profile, and
making the judgment such that when a change of the diagnosis impedance from the impedance of the characteristic profile can be judged on the basis of the characteristic profile, the cause of the change resides in the prescribed site, whereas when the change cannot be judged, the cause of the change does not reside in the prescribed site.

4. The failure diagnosis method of a fuel cell system according to claim 3, wherein
the fuel cell system includes a power generation section having the fuel cell; an oxidizer gas feed section for feeding an oxidizer gas for undergoing power generation of the fuel cell into the power generation section; and a hydrogen gas feed section having a reformer for feeding a hydrogen gas for undergoing power generation of the fuel cell into the power generation section,
the prescribed site includes at least one of a specific site within the hydrogen gas feed section, a specific site within the oxidizer gas feed section and a specific site within the power generation section, and
the determination is achieved by changing operation conditions of these specific sites.

5. The failure diagnosis method of a fuel cell system according to claim 4, wherein
the specific site of the hydrogen gas feed section is a first pump for feeding water for reformation into the reformer, a booster for feeding a raw material into the reformer, and a burner for heating the reformer, and
the reformer is included as the prescribed site.

6. The failure diagnosis method of a fuel cell system according to claim 4, wherein
the specific site of the oxidizer gas feed section is a blower for taking and introducing the outside air into the side of the fuel cell, a humidifier for humidifying the outside air as taken by the blower, and a second pump for feeding water into the humidifier, and a filter as provided before the blower is included as the prescribed site.

7. The failure diagnosis method of a fuel cell system according to claim 4, wherein
the specific site of the power generation section is the fuel cell and a third pump for feeding cooling water into the fuel cell, and
the fuel cell is included as the prescribed site.

8. The failure diagnosis method of a fuel cell system according to claim 1, wherein
the specific site of the fuel cell is determined by considering the fuel cell as an equivalent circuit having the prescribed portion as a resistance and computing the impedance for every alternating current with a different frequency.

9. The failure diagnosis method of a fuel cell system according to claim 1, wherein an amplitude of the alternating current has a size of substantially from 5% to 10% of the direct current value.

10. A failure diagnosis device of a fuel cell system including
an alternating current source for feeding a frequency variable alternating current which is superposed on a direct current generated from a fuel cell of a fuel cell system,
an impedance computation instrument for computing an impedance corresponding to a prescribed portion of the fuel cell of the fuel cell system from a signal obtained by superposing the alternating current on the direct current, and
a diagnosis instrument in which when in comparison of the impedance with an impedance as computed under a previously determined standard operation condition, an abnormality is present in the prescribed portion of the fuel cell, whether a cause of the abnormality of the prescribed portion resides in any one or plural prescribed sites constituting the fuel cell system is determined by using the comparison result, wherein
the diagnosis instrument achieves the determination by
using a corresponding relation between an operation condition of each prescribed site of the fuel cell system and an impedance of each prescribed portion of the fuel cell under the standard operation condition as a characteristic profile,
as the certain operation condition, changing the operation condition of the prescribed site more greatly than the standard operation condition and comparing a diagnosis impedance as measured corresponding to the change with an impedance of the characteristic profile, and
making the judgment such that when a change of the diagnosis impedance from the impedance of the characteristic profile can be judged on the basis of the characteristic profile, its cause resides in that prescribed site, whereas when the change cannot be judged, its cause does not reside in that prescribed site.

11. (canceled)

12. A fuel cell system having the failure diagnosis device of a fuel cell system according to claim 10, which includes a power generation section having the fuel cell; an oxidizer gas feed section for feeding an oxidizer gas for undergoing power generation of the fuel cell into the power generation section; and a hydrogen gas feed section having a reformer for feeding a hydrogen gas for undergoing power generation of the fuel cell into the power generation section, wherein
the prescribed site includes at least one of a specific site within the hydrogen gas feed section, a specific site within the oxidizer gas feed section and a specific site within the power generation section, and
the determination instrument achieves the determination by changing operation conditions of these specific sites.

13. The fuel cell system according to claim 12, which further include a control instrument for changing operation conditions of the specific site within the hydrogen feed section, the specific site within the oxidizer gas feed section and the specific site within the power generation section, wherein
the diagnosis instrument achieves the determination by obtaining parameters of the changes of the operation condition from the control instrument.

14. The fuel cell system according to claim 12, wherein
the specific site of the hydrogen gas feed section is a first pump for feeding water for reformation into a reformer, a booster for feeding a raw material into the reformer, and a burner for heating the reformer, and
the reformer is included as the prescribed site.

15. The fuel cell system according to claim 12, wherein
the specific site of the oxidizer gas feed section is a blower for taking and introducing the outside air into the side of the fuel cell, a humidifier for humidifying the outside air as taken by the blower, and a second pump for feeding water into the humidifier, and
a filter as provided before the blower is included as the prescribed site.

16. The fuel cell system according to claim 12, wherein
the specific site of the power generation section is the fuel cell and a third pump for feeding cooling water into the fuel cell, and
the fuel cell is included as the prescribed site.

17. (canceled)

18. A recording medium for recording the program according to claim 17, which can be processed by a computer, records a program for making a computer function as
an impedance computation instrument for computing an impedance corresponding to a prescribed portion of a fuel cell of a fuel cell system from a signal obtained by superposing the alternating current on the direct current, and
a diagnosis instrument in which when in comparison of the impedance with an impedance as computed under a previously determined standard operation condition, an abnormality is present in the prescribed portion of the fuel cell, whether a cause of the abnormality of the prescribed portion resides in any one or plural prescribed sites constituting the fuel cell system is determined by using the comparison result,
of a failure diagnosis device of a fuel cell system according to claim 10.

19. A diagnosis site specifying method of a fuel cell system for specifying a prescribed site, which is used for the failure diagnosis method of a fuel cell system according to claim 1 against a fuel cell system including a power generation section having a fuel cell, an oxidizer gas feed section for feeding an oxidizer gas into the power generation section for the purpose of power generation of the fuel cell, and a hydrogen gas feed section for feeding a hydrogen gas into the power generation section for the purpose of power generation of the fuel cell, the method including:
a step for computing impedances of plural prescribed portions of the fuel cell of the fuel cell system from a signal obtained by superposing an alternating current on a direct current as generated from the fuel cell system,
a step for specifying at least one of a specific site within the hydrogen gas feed section, a specific site within the oxidizer gas feed section and a specific site within the power generation section as an operation site, and
a step for changing the operation condition to make the fuel cell system act and at that time, observing whether the impedance of any one of the plural prescribed portions of the fuel cell is changed, thereby specifying the operation site as the prescribed site.
